(19) United States
(12) Patent Application Publication
(10) Pub. No.: US 2008/0212047 A1
(43) Pub. Date: Sep. 4, 2008

(54) Exposure apparatus, exposing method, and device fabricating method

(75) Inventor: Ayako Sugimoto, Kumagaya-shi (JP)

Correspondence Address: OLIFF & BERRIDGE, PLC, P.O. BOX 320850, ALEXANDRIA, VA, 22320-4850, US

(73) Assignee: NIKON CORPORATION, TOKYO (JP)

(21) Appl. No.: 12/003,451

(22) Filed: Dec. 26, 2007

Related U.S. Application Data
(60) Provisional application No. 60/877,387, filed on Dec. 28, 2006.

(51) Int. Cl. G03B 27/42; G03F 7/00; G03B 27/52

(52) U.S. Cl. 355/30; 430/30; 355/53

(57) ABSTRACT

An exposure apparatus comprises: a first optical member for acquiring positional information about the substrate through a first liquid that is for measurement; a second optical member that emits the exposure beam; a first movable member that holds the substrate and is capable of moving within a prescribed area that includes a first position, which opposes the first optical member, and a second position, which opposes the second optical member; and a first liquid holding member that can be positioned at the first position; wherein, by disposing at least one of the first movable member and the first liquid holding member at the first position, a first space, which is capable of holding the first liquid, continues to be formed between the first optical member and at least one of the first movable member, the substrate, which is held by the first movable member, and the first liquid holding member.

### CROSS-REFERENCE TO RELATED APPLICATION

This application is non-provisional application claiming benefit of provisional application No. 60/877,387, filed Dec. 28, 2006, the contents of which am incorporated herein by reference.

### BACKGROUND

1. Field of the Invention

The present invention relates to an exposure apparatus and an exposing method, as well as to a device fabricating method.

2. Description of Related Art

Among exposure apparatuses used in a photolithographic process, an immersion exposure apparatus is known that exposes a substrate through a liquid, as disclosed in Japanese Patent Application, Publication No. 2004-289128A (corresponding U.S. Pat. No. 7,075,616), PCT International Publication No. WO2005/074014 (corresponding Europe Patent Application, Publication No. 1,713,113), and PCT International Publication No. WO2005/081293 (corresponding Europe Patent Application, Publication No. 1,717,845).

With an immersion exposure apparatus, it is conceivable to acquire positional information about a substrate (e.g., by detecting an alignment mark on the substrate) by irradiating the substrate with a detection beam through an optical member and a liquid that is between the substrate and that optical member, and/or by receiving the detection beam from the substrate through the liquid and the optical member. In this case, if the substrate is moved away from the optical path of the detection been, then the liquid cannot be held between the optical member and the suite. In this case, if the substrate is moved after all of the liquid is recovered then there is a possibility that the throughput of the exposure apparatus will decrease. Id addition, if all of the liquid is recovered, then the surface of the optical member that makes contact with the liquid changes from a wet state to a dry state. In this case, the vaporization of the liquid that remains on the surface of the optical member causes, for example, a residue of the liquid (a watermark) to form on the surface of the optical member and causes the temperature of the optical member to change, and therefore there is a possibility that the performance of the optical member will degrade. If the performance of the optical member degrades, then positional information about the substrate cannot be acquired accurately, and there is therefore a possibility that exposure accuracy will degrade.

A purpose of some aspects of the invention is to provide an exposure apparatus and an exposing method, as well as a device fabricating method, in an immersion exposure apparatus that can accurately acquire positional information about a substrate and can expose the subsume satisfactorily and with good efficiency.

Another purpose is to provide an exposure apparatus and an exposing method, as well as a device fabricating method, in an immersion exposure apparatus that prevents deterioration of an optical member for acquiring positional information about the substrate, and therefore can ache positional information about the substrate accurately and expose the substrate satisfactorily and with good accuracy.

### SUMMARY

A first aspect of the invention provides an exposure apparatus that exposes a substrate by irradiating such with an exposure beam and comprises: a first optical member through which and a first liquid is acquired positional information about the substrate; a second optical member that emits the exposure beam; a first movable member that holds the substrate and is capable of moving within a prescribed area that includes a first position, which opposes the first optical member, and a second position, which opposes the second optical member, and a first liquid holding member that is capable of moving to the first position; wherein, by disposing at least one of the first movable member and the first liquid holding member at the first position, a first space, which is capable of holding the first liquid, continues to be formed between at least one of the first movable member, the substrate, which is held by the first movable member, and the first liquid holding member on one side and the first optical member on the other side.

According to the first aspect of the invention, it is possible to prevent deterioration of the first optical member for acquiring positional information about the substrate, which makes it possible to acquire positional information about the substrate accurately and to expose the substrate satisfactorily and efficiently.

A second aspect of the invention provides a device fabricating method, comprising exposing a substrate by use of the exposure apparatus according to the abovementioned aspect, and developing the exposed substrate.

According to the second aspect of the invention, it is possible to use the exposure apparatus that can expose the substrate satisfactorily and efficiently to fabricate a device.

A third aspect of the invention provides an exposing method for exposing a substrate with an exposure beam, the method comprising: holding the substrate to a movable member, acquiring positional information about the substrate, which is held by the movable member through a first liquid and a first optical member, after positional information about the substrate is acquired, irradiating the substrate, which is held by the movable member, with the exposure beam through a second optical member and a second liquid; and, after positional information about the substrate is acquired and before an exposure of the substrate, which is held by the movable member, starts, disposing a liquid holding member at a position that opposes the first optical member so as to continue forming a space, which is capable of holding the first liquid, between the liquid holding member and the first optical member.

According to the third aspect of the invention, it is possible to prevent deterioration of the first optical member for acquiring positional information about the substrate, which makes it possible to acquire positional information about the substrate accurately and to expose the substrate satisfactorily and efficiently.

A fourth aspect of the invention provides an exposing method for exposing a substrate with an exposure beam, the method comprising: holding a substrate to a first movable member; acquiring positional information about the subs, which is held by the first movable member, in a state in which a first liquid is held between the substrate held by the first movable member and a first optical member; exposing the substrate held by the first movable member through a second optical member and a second liquid after the acquisition of the positional information about the substrate held by the first movable member; holding a substrate to a second movable member; acquiring positional information about the substrate, which is held by the second movable member, in a state in which the first liquid is held between the substrate held by the second movable member and the first optical member; and exposing the substrate held by the second movable member through the second optical member and the second liquid after the exposure of the substrate held by the first movable member and before the acquisition of the positional information about the substrate held by the second movable member, wherein the first liquid continues to be held below the first optical member during transition from a first state in which the first liquid is held between the substrate held by the first movable member and the first optical member to a second state in which the first liquid is held between the substrate held by the second movable member and the first optical member.

According to the fourth aspect of the invention, it is possible to prevent deterioration of the first optical member for acquiring positional information about the substrate, which makes it possible to acquire positional information about the substrate accurately and to expose the substrate satisfactorily and efficiently.

A fifth aspect of the invention provides a device fabricating method, comprising exposing a substrate by use of the exposing method according to the abovementioned aspect; and developing the exposed substrate.

According to the fifth aspect of the invention it is possible to use the exposing method that can expose the substrate satisfactorily and efficiently to fabricate a device.

According to the some aspects of the invention, it is possible to expose a substrate satisfactory and efficiently, and thereby to fabricate, with good productivity, a device that has a desired performance.

### BRIEF DESCRIPTION OF THE DRAWINGS

FIG. 1 is a schematic block diagram that shows one example of an exposure apparatus according to a first embodiment.

FIG. 2 is a plan view of a substrate stage and a measurement stage.

FIG. 3 is an enlarged cross sectional view of the vicinity of a first nozzle member.

FIG. 4 is an explanatory view of a cap holding mechanism.

FIG. 5 is an enlarged cross sectional view of the vicinity of a second nozzle member.

FIG. 6 is a schematic diagram for explaining one example of the operation of the exposure apparatus according to the first embodiment.

FIG. 7 is a schematic diagram for explaining one example of the operation of the exposure apparatus according to the first embodiment.

FIG. 8 is a schematic diagram for explaining one example of the operation of the exposure apparatus according to the first embodiment.

FIG. 9 is a schematic diagram for explaining one example of the operation of the exposure apparatus according to the first embodiment.

FIG. 10 is a schematic diagram for explaining one example of the operation of the exposure apparatus according to the first embodiment.

FIG. 11 is a schematic diagram for explaining one example of the operation of the exposure apparatus according to the first embodiment.

FIG. 12 is a schematic diagram for explaining one example of the operation of the exposure apparatus according to the first embodiment.

FIG. 13 is a schematic diagram for explaining one example of the operation of the exposure apparatus according to the first embodiment.

FIG. 14 is a schematic block diagram that shows one example of an exposure apparatus according to a second embodiment.

FIG. 15 is a schematic block diagram that shows one example of an exposure apparatus according to a third embodiment.

FIG. 16 is a plan view of the first substrate stage and the second substrate stage.

FIG. 17 is an explanatory view of a second cap holding mechanism.

FIG. 18 is a schematic diagram for explaining one example of the operation of the exposure apparatus according to the third embodiment.

FIG. 19 is a schematic diagram for explaining one example of the operation of the exposure apparatus according to the third embodiment.

FIG. 20 is a schematic diagram for explaining one example of the operation of the exposure apparatus according to the third embodiment.

FIG. 21 is a schematic diagram for explaining one example of the operation of the exposure apparatus according to the third embodiment.

FIG. 22 is a schematic diagram for explaining one example of the operation of the exposure apparatus according to the third embodiment.

FIG. 23 is a schematic diagram for explaining one example of the operation of the exposure apparatus according to the third embodiment.

FIG. 24 is an oblique view that shows part of the exposure apparatus according to a fourth embodiment.

FIG. 25 is an oblique view that shows part of the exposure apparatus according to the fourth embodiment.

FIG. 26 is a flow chart diagram that depicts one example of a process for fabricating a microdevice.

### DESCRIPTION OF THE PREFERRED EMBODIMENTS

The following explains the embodiments of the present invention, referencing the drawings, but the present invention is not limited thereto. Furthermore, the following explanation defines an XYZ orthogonal coordinate system, and the positional relationships of the members are explained by referencing this system. Furthermore, prescribed directions within the horizontal plane are the X axial directions, directions that are orthogonal to the X axial directions in the horizontal plane are the Y axial directions, and directions that are orthogonal to the X axial directions and the Y axial directions (i.e., the vertical directions) are the Z axial directions. In addition, the rotational (the inclined) directions about the X, Y, and Z axes are the θX, θY, and θZ directions, respectively.

### First Embodiment

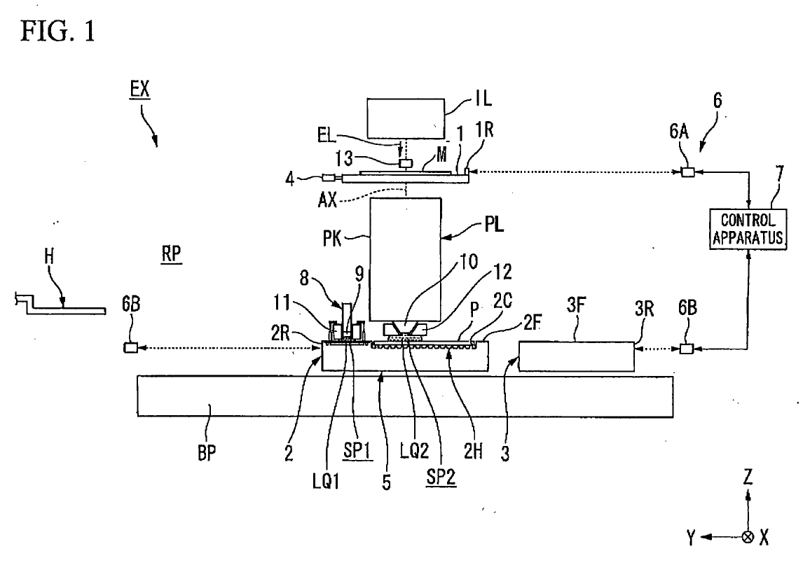

The first embodiment will now be explained. FIG. 1 is a schematic block diagram that shows an exposure apparatus EX according to a first embodiment. The present embodiment explains an exemplary case wherein the exposure apparatus EX is an exposure apparatus that comprises a substrate stage 2 that holds a substrate P and a measurement stage 3 whereon a measuring instrument is mounted that is capable of performing a measurement related to an exposure without holding the substrate P, as disclosed in, for example, Japanese Patent Application, Publication No. 11-135400A and Japanese Patent Application, Publication No. 2000-164504A (corresponding U.S. Pat. No. 6,897,963). The measuring instrument comprises a fiducial member wherein a fiducial mark is formed and/or various photoelectric sensors.

In FIG. 1, the exposure apparatus EX comprises: a mask stage 1, which is capable of holding and moving a mask M; the substrate stage 2, which is capable of holding and moving the substrate P; the measurement stage 3, which is capable of moving independently of the substrate stage 2 and whereon a measuring inset is mounted that is capable of performing a measurement related to the exposure without holding the substrate P; a drive system 4, which moves the mask stage 1; a drive system 5, which moves the substrate stage 2 and the measurement stage 3; a measurement system 6, which comprises laser interferometers that measure positional information of the stages 1, 2, 3; an illumination system IL, which illuminates the mask M with exposure lift EL; a projection optical system PL, which projects an image of a pattern of the mask M that is illuminated with the exposure light EL onto the substrate P; and a control apparatus 7 that controls the operation of the entire exposure apparatus EX.

Furthermore, the substrate P referenced here is a substrate for fabricating a device, and can include one that has a base material, such as a semiconductor wafer such as a silicon wafer, whereon a film, such as a photosensitive material (photoresist), is formed, or include one on which various types of membrane such as a protective membrane (top coat membrane) in addition to the photosensitive film is coated. The mask M includes a reticle wherein a device pattern is formed that is reduction projected onto the substrate P. In addition, a transmitting type mask is used as the mask M in the present embodiment, but a reflection type mask can also be used. The transmission-type mask is not limited to a binary mask on which a pattern is formed with a shading film, and also includes, for example, a phase-shift mask such as a half-tone type or a spatial frequency modulation type.

In addition, the exposure apparatus EX of the present embodiment comprises an alignment system 8 for acquiring positional information about the substrate P. The alignment system 8 of the present embodiment is an off-axis type alignment system and is capable of detecting, for example, an alignment mark on the substrate P and a fiducial mark FM1 of a fiducial member 14, which is provided to the measurement stage 3. The present embodiment explains an exemplary case wherein the alignment system 8 is a field image alignment (FIA) system of the type disclosed in, for example, Japanese Patent Application, Publication No. H4-65603A (corresponding U.S. Pat. No. 5,493,403) that irradiates a detection target mark (alignment mark, fiducial mark, etc.) on the substrate P with a broadband detection light beam that does not photosensitize the photosensitive material on the substrate P; uses an imaging device (e.g., a CCD) to cape an image of an index (an index mark on an index plate provided in the alignment system) and an image of the detection target mark that is imaged on a light receiving surface by the light reflected from that detection target mark; and measures the position of the mark by image processing these signals.

The exposure apparatus EX of the present embodiment is an exposure apparatus that applies the liquid immersion method to shorten the exposure wavelength substantially, improve the resolution, as well as increase the depth of focus substantially, and exposes the substrate P by radiating the exposure light EL through the projection optical system PL and exposure liquid LQ2 onto the substrate P. The projection optical system PL irradiates the substrate P with exposure light EL trough the exposure liquid LQ2.

In addition, the alignment system 8 of the present embodiment detects, for example, an alignment mark on the substrate P and a fiducial mark FM1 on the measurement stage 3 through measurement liquid LQ1 in order to acquire positional information about the substrate P.

The alignment system 8 comprises an optical element 9, which contacts the measurement liquid LQ1. The optical element 9 of the alignment system 8 is capable of holding the measurement liquid LQ1 between the optical element 9 and an object that is disposed at a position that opposes the optical element 9.

The projection optical system PL comprises an optical element 10, which contacts the exposure liquid LQ2. The optical element 10 of the projection optical system PL is capable of holding the exposure liquid LQ2 between the optical element 10 and an object that is disposed at a position that opposes the optical element 10. The optical element 10 is the optical element of the plurality of optical elements of the projection optical system PL that is closest to an image plane of the projection optical system PL, and emits the exposure light EL.

In the explanation below, the measurement liquid LQ1 is properly called the first liquid LQ1, and the optical element 9 of the alignment 8 is properly called the first optical element 9. In addition, the exposure liquid LQ2 is properly called the second liquid LQ2, and the optical element 10 of the projection optical system PL is properly called the second optical element 10. In addition, the position that opposes the first optical element 9 is properly called the first position, and the position that opposes the second optical element 10 is properly called the second position.

In the present embodiment, the same liquid (pure water) is used for the first liquid LQ1 and the second liquid LQ2.

Disposing an object at the first position that opposes the first optical element 9 forms a first space SP1, which is capable of holding the first liquid LQ1, between the first optical element 9 and that object. In addition, disposing an object at the second position forms a second space SP2, which is capable of holding the second liquid LQ2, between the second optical element 10 and that object.

In the present embodiment, the objects that are capable of opposing the first optical element 9 and the second optical element 10, i.e., the objects that are capable of being disposed at (capable of moving to) the first position and the second position, are capable of moving on the light emergent side of the first optical element 9 and the light emergent side (image plane side) of the second optical element 10. In the present embodiment, the objects that are capable of being disposed at (capable of moving to) the first position and the second position include at least one of the substrate stage 2 and the measurement stage 3. In addition, the objects that are capable of being disposed at (capable of moving to) the first position and the second position include a cap member 30, which is discussed later. Furthermore, the substrate P, which is held by the substrate stage 2, is also capable of being disposed at (capable of moving to) the first position and the second position.

In the present embodiment, the first position is a position that is directly below the first optical element 9, and the second position is a position that is directly below the second optical element 10.

In addition, the exposure apparatus EX in the present embodiment comprises: a first nozzle member 11 that forms a first immersion space of the first liquid LQ1 so that the first liquid LQ1 fills the space between the first optical element 9 and the object that is disposed at the first position; and a second nozzle member 12 that is capable of forming a second immersion space of the second liquid LQ2 so that the second liquid LQ2 fills the space between the second optical element 10 and the object that is disposed at the second position. The immersion spaces are spaces that are filled with liquid.

In the present embodiment, the first immersion space is formed so that part of the area (a local area) of the front surface of the object that is disposed at the first position is covered with the first liquid LQ1. In addition, the second immersion space is formed so that part of the area (a local area) of the front spice of the object that is disposed at the second position is covered with the second liquid LQ2. The first nozzle member 11 and the second nozzle member 12 are spaced apart in the Y directions, and the first immersion space formed by the first nozzle member 11 and the second immersion space formed by the second nozzle member 12 are spaced apart in the Y directions.

The illumination system IL illuminates a prescribed illumination region on the mask M with the exposure light EL, which has a uniform luminous flux intensity distribution. Examples of light that can be used as the exposure light EL emitted from the illumination system IL include: deep ultraviolet light (DUV light) such as bright line (g-line, h-line, or i-line) light-emitted from, for example, a mercury lamp, and KrF excimer laser light (248 nm wavelength); and vacuum ultraviolet light (VUV light), such as ArF excimer laser light (193 nm wavelength) and F₂ laser light (157 nm wavelength). ArF excimer laser light is used as the exposure light EL in the present embodiment.

The mask stage 1, in a state wherein it holds the mask M, is movable in the X axial, Y axial, and θZ directions by the drive system 4, which comprises actuators such as linear motors. Laser interferometers 6A of the measurement system 6 measure the positional information of the mask stage 1 (and, in turn, the mask M). The laser interferometers 6A use measurement mirrors 1R, which are provided on the mask stage 1, to measure the positional information of the mask stage 1 in the X axial, Y axial, and θZ directions. Based on the measurement results of the measurement system 6, the control apparatus 7 controls the position of the mask M, which is held by the mask stage 1, by driving the drive system 4.

In the present embodiment, a TTR type alignment system 13, which uses light of a wavelength that is the same as the exposure wavelength, is provided in the vicinity of the mask stage 1. The alignment system 13 is capable of simultaneously observing an alignment mark on the mask M and a fiducial mark FM2 of the fiducial member 14, which is provided to the measurement stage 3, through the projection optical system PL. The present embodiment explains an exemplary case wherein the alignment system 13 is a VRA (visual reticle alignment) type alignment system that detects the position of the mark to be detected by irradiating such with light and image processing image data of the mark to be detected captured by, for example, a CCD camera, as disclosed in, for example, Japanese Patent Application, Publication No. H7-176468A (corresponding U.S. Pat. No. 5,646,413). The alignment system 13 detects the fiducial mark FM2 of the fiducial member 14 through the projection optical system PL and the second liquid LQ2.

The projection optical system PL projects an image of the pattern of the mask M to the substrate P at a prescribed projection magnification. The projection optical system PL comprises a plurality of optical elements, which is held by a lens barrel PK. The projection optical system PL of the present embodiment is a reduction system that has a projection magnification of; for example, ¼, ⅕, or ⅛. Furthermore, the projection optical system PL may be a reduction system, a unity magnification system, or an enlargement system. In the present embodiment, an optical axis AX of the projection optical system PL is parallel to the Z axial directions. In addition, the projection optical system PL may be: a dioptric system that does not include catoptric elements; a catoptric system that does not include dioptric elements; or a catadioptric system that includes both catoptric elements and dioptric elements. In addition, the projection optical system PL may form either an inverted image or an erect image.

The substrate stage 2 comprises a substrate holder 2H, which releasably holds the substrate P, holds the substrate P using the substrate holder 2H, and is capable of moving within a prescribed area on a base member BP, which includes the first position that opposes the first optical element 9 and the second position that opposes the second optical element 10. The substrate stage 2 comprises a recessed part 2C wherein the substrate holder 2H is disposed. An upper surface 2F that surrounds the recessed part 2C of the substrate stage 2 is substantially flat and is substantially the same height as (is flush with) the front surface of the substrate P, which is held by the substrate holder 2H.

The measurement stage 3 is equipped with a measuring instrument, which is capable of performing measurements related to exposure without holding the substrate P, and is capable of moving within the prescribed area on the base member BP, which includes the first position and the second position as discussed above. An upper surface 3F of the measurement stage 3 is substantially flat.

The drive system 5 includes actuators, such as linear motors, and is capable of moving the substrate stage 2 and the measurement stage 3 on the base member BP with six degrees of freedom, i.e., the X, Y, and Z axial directions and the θX, the θY, and the θZ directions. The control apparatus 7 controls the drive system 5 and is capable of moving the substrate stage 2 and the measurement stage 3 within the prescribed areas in an XY plane that includes the first position and the second position, and is also capable of moving with six degrees of freedom.

Positional information of the substrate stage 2 (the substrate P) and positional information of the measurement stage 3 are measured by laser interferometers 6B of the measurement system 6. The laser interferometers 6B use measurement mirrors 2R, 3R that are provided on the stages 2, 3, respectively, to measure the positional information of the stages 2, 3 in the X axial Y axial, and θZ directions. In addition, a focus leveling detection system (not shown) of the measurement system 6 detects surface positional information (positional information related to the Z axial, θX, and θY directions) about the front surface of the substrate P held by the substrate holder 2H of the substrate stage 2, and surface positional information about a prescribed area on the upper surface 3F of the measurement stage 3. By driving the drive system 5 based on the measurement results of the laser interferometers 6B of the measurement system 6 and on the detection results of the focus leveling detection system, the control apparatus 7 controls the position of the substrate stage 2 and the substrate P held by the substrate holder 2H of the substrate stage 2, as well as the position of the measurement stage 3.

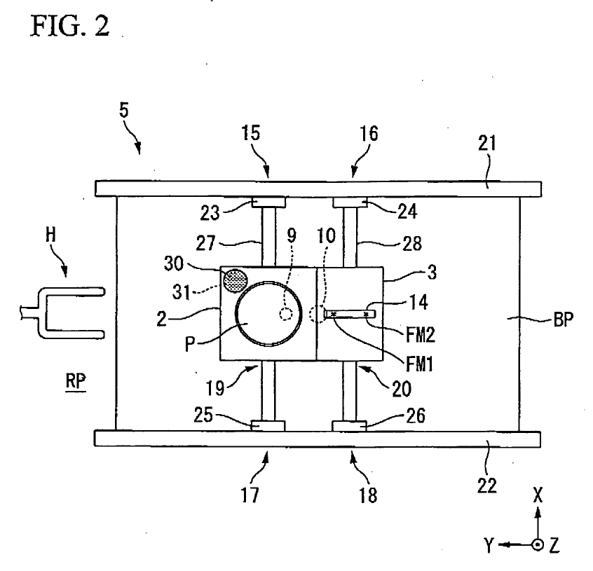

FIG. 2 is a plan view of the substrate stage 2 and the measurement stage 3. As shown in FIG. 2, the fiducial member 14, whereon the fiducial marks FM1, FM2 are formed, is disposed on the measurement stage 3. The first fiducial mark FM1, which is detected by the alignment system 8, and the second fiducial mark FM1, which is detected by the alignment system 13, are formed in the fiducial member 14 in accordance with a prescribed positional relationship. In order to define the positional relationship between the image of the pattern of the mask M that is formed through the projection optical system PL and a shot region on the substrate P, the fiducial member 14 is used to measure the positional relationship (baseline information) within the XY plane between a projection position of the image of the pattern of the mask M formed by the projection optical system PL and a detection reference position of the alignment system 8.

In addition, although not shown, the measurement stage 3 is provided with: a nonuniformity sensor, as disclosed in, for example, Japanese Patent Application, Publication No. S57-117238A (corresponding U.S. Pat. No. 4,465,368), and Japanese Patent Application, Publication No. 2001-267239A (corresponding U.S. Pat. No. 6,721,039); an aerial image measuring sensor, as disclosed in, for example, Japanese Patent Application, Publication No. 2002-14005A and Japanese Patent Application, Publication No. 2002-198303A (corresponding U.S. patent application, Publication No. 2002/0041377); an irradiance sensor (luminous flux intensity sensor) as disclosed in, for example, Japanese Patent Application, Publication No. H11-16816A (corresponding U.S. patent application, Publication No. 2002/0061469); and a wavefront aberration measuring instrument as disclosed in, for example, PCT International Publication No. WO99/60361 (corresponding U.S. Pat. No. 6,819,414), Japanese Patent Application, Publication No. 2002-71514A, and U.S. Pat. No. 6,650,399.

In FIG. 2, the drive system 5 that moves the substrate stage 2 and the measurement stage 3 comprises a plurality of linear motors 15, 16, 17, 18, 19, 20. The drive system 5 comprises two Y axis guide members 21, 22, each of which extends in the Y axial directions. Each of the Y axis guide members 21, 22 comprises a magnet unit that has a plurality of permanent magnets. One of the Y axis guide members, i.e., the Y as guide member 21, so two slide members 23, 24 so that they are movable it the Y axial directions, and the other Y axis guide member, i.e., the Y axis guide member 22, supports two slide members 25, 26 so that they are movable in the Y axial directions. Each of the slide members 23, 24, 25, 26 comprises a coil unit, which has an armature coil. Namely, in the present embodiment, the slide members 23, 24, each of which has a coil unit, and the Y axis guide member 21, which has a magnet unit, form the moving coil type Y ads linear motors 15, 16. Similarly, the slide members 25, 26, each of which has a coil unit, and the Y axis guide member 22, which has a magnet unit, form the moving coil type Y axis linear motors 17, 18.

The drive system 5 comprises two X axis guide members 27, 28, each of which extends in the X axial directions. Each of the X axis guide members 27, 28 comprises a coil unit, which has an armature coil. One of the X axis guide members, i.e., the X axis guide member 27, supports the sliding member that is connect to the substrate stage 2 so that it is movable in the X axial directions, and the other X axis guide member, i.e. the X axis guide member 28, supports the sliding member that is connected to the measurement stage 3 so that it is movable in the X axial directions. Each of the sliding members comprises a magnet unit, which has a plurality of permanent magnets. Namely, in the present embodiment, the sliding member that has a magnet unit that is connected to the substrate step 2 and the X axis guide member 27 that has a coil unit form the moving magnet type X axis linear motor 19, which drives the substrate stage 2 in the X axial directions. Similarly, the sliding member that has a magnet unit that is connected to the measurement stage 3 and the X axis guide member 28 that has the coil unit form the moving magnet type X axis linear motor 20, which drives the measurement stage 3 in the X axial directions.

The slide members 23, 25 are fixed to one end and another end, respectively, of the X axis guide member 27, and the slide members 24, 26 are fixed to one end and another end, respectively, of the X axis guide member 28. Accordingly, the X axis guide member 27 is movable in the Y axial directions by the Y axis linear motors 15, 17, and the X axis guide member 28 is movable in the Y axial directions by the Y axis linear motors 16, 18.

The control apparatus 7 can control the position of the substrate stage 2 in the θZ directions by creating a slight difference in the thrusts generated by each of they axis linear motors 15, 17, and can control the position of the measurement stage 3 in the θZ directions by creating slight differences in the thrusts generated by each of the Y axis linear motors 16, 18.

In addition, although not shown, the drive system 5 comprises actuators, such as voice coil motors, that are capable of moving (jogging) each of the stages 2, 3 with six degrees of freedom.

In addition, the exposure apparatus EX comprises a transport system H that exchanges the substrate P with another. The control apparatus 7 is capable of performing a substrate exchange operation, which includes an operation that uses the transport system H to unload an exposure processed substrate P from the substrate stage 2, which has moved to a substrate exchange position (loading position) RP, and an operation that loads the next substrate P to be exposure processed to the substrate stage 2.

In the present embodiment, the exposure apparatus EX composes the cap member 30, which is capable of being disposed at the first position that opposes the first optical element 9, and a cap holder 31, which releasably holds the cap member 30 to the substrate stage 2.

When the cap member 30 is disposed at the first position, the first space SP1 that is capable of holding the first liquid LQ1 between the first optical element 9 and the cap member 30 is formed. The cap member 30 is formed in accordance with the size and shape of the first nozzle member 11 (the first optical element 9). In the present embodiment the cap member 30 is a substantially circular, plate shaped member within the XY plane. The surface of the cap member 30 is liquid repellent with respect to the first liquid LQ1. In the present embodiment, the cap member 30 is formed from a liquid repellant material such as a fluororesin ma e.g., polytetrafluoroethylene (PTFE), Tetra fluoro ethylene-perfluoro alkylvinyl ether copolymer (PFA). Furthermore, the cap member 30 may be formed from a prescribed metal, such as stainless steel or titanium, and its surface may be covered with a material that is liquid repellent.

The cap holder 31 is disposed on the substrate stage 2 and releasably holds the cap member 30. Namely, the cap member 30 is attachable to and detachable from the substrate stage 2. In the present embodiment, the surface (the upper surface) of the cap member 30 held by the cap holder 31 and the upper surface 2F of the substrate stage 2 are substantially flush with one another.

In the present embodiment, the cap holder 31 comprises a vacuum chuck mechanism and chucks the cap member 30. Furthermore, if the cap member 30 is formed with a magnetic body (metal), then the cap holder 31 has a mechanism that holds the cap member 30 with magnetic force.

In the present embodiment, the exposure apparatus EX comprises one cap member 30. The control apparatus 7 holds the cap member 30 with the cap holder 31 while the operation that uses at least the alignment system 8 to acquire positional information about the substrate P is performed; specifically, while the operation of detecting an alignment mark on the substrate P and the fiducial mark FM1 on the measurement stage 3 through at least the first optical element 9 is performed.

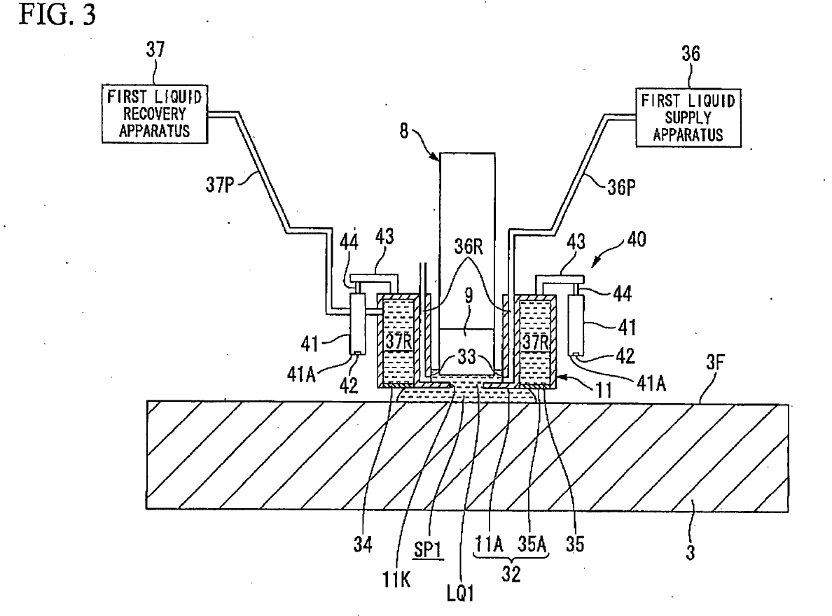

FIG. 3 is a side sectional view that shows the vicinity of the first nozzle member 11. Furthermore, the second nozzle member 12 is not shown in FIG. 3. In addition, the following explains an exemplary case wherein the measurement stage 3 is disposed at a position that opposes the first optical element 9 and the first nozzle member 11, and the first space SP1 is formed between the first optical element 9 and the upper surface 3F of the measurement stage 3.

The first nozzle member 11 comprises a lower surface 32, and is capable of holding the first liquid LQ1 between the lower surface 32 and the upper sleeve 3F of the measurement stage 3. Holding the first liquid LQ1 between the lower surface 32 of the first nozzle member 11 and the upper surface 3F of the measurement stage 3 forms the first immersion space between the first optical element 9 and the first nozzle member 11 on one side, and the measurement stage 3 on the other side so that the first liquid LQ1 fills the first space SP1.

The first nozzle member 11 comprises a supply port 33, which is capable of supplying the fit liquid LQ1, and a recovery port 34, which is capable of recovering the first liquid LQ1. The supply pot 33 is capable of supplying the first liquid LQ1 to the first space SP1. In the present embodiment, a porous member (mesh) 35 is disposed in the recovery port 34. In the embodiment, the porous member 35 includes a plate on which a plurality of circular holes (trough holes) are provided. However, as the porous member 35, a sintered member in which a plurality of pores are formed (for example, a sintered metal), foam member (for example, a foam metal), or the like may be used. The first nozzle member 11 comprises an opening 11K, wherethrough the detection beam from the first optical element 9 and/or the detection beam from the substrate P passes. The lower surface 32 of the first nozzle member 11 comprises a flat surface 11A, which is disposed so a it surrounds the opening 11K and a lower surface 35A (the recovery port 34) of the porous member 35 that is disposed around the flat surface 11A.

The supply port 33 is connected to a first liquid supply apparatus 36, which is capable of feeding the first liquid LQ1 through a supply pipe 36P and a supply passageway 36R, which is formed inside the first nose member 11. The recovery port 34 is connected to a first liquid recovery apparatus 37 that is capable of recover at least the first liquid LQ1 through a recovery passageway 37R, which is formed inside the first nozzle member 11, and a recovery pipe 37P.

The it liquid supply apparatus 36 is capable of feeding the first liquid LQ1, which is pure and temperature adjusted. In addition, the first liquid recovery apparatus 37 comprises, for example, a vacuum system, and is capable of recovering the first liquid LQ1 through the recovery port 34. The control apparatus 7 controls the operation of the first liquid supply apparatus 36 and the first liquid recovery apparatus 37. After the first liquid LQ1, which is fed from the first liquid supply apparatus 36, flows through the supply pipe 36P and the supply passageway 36R of the first nozzle member 11, it is supplied to the first space SP1 via the supply port 33. In addition, after the first liquid LQ1, which is recovered via the recovery port 34 by driving the first liquid recovery apparatus 37, flows through the recovery passageway 37R of the first nozzle member 11, it is recovered by the first liquid recovery apparatus 37 through the recovery pipe 37P. The control apparatus 7 performs the operation of supplying liquid via the supply port 33 and the operation of recovering liquid via the recovery port 34 in parallel; thereby, the first immersion space of the first liquid LQ1 is formed so that the first space SP1 between the first optical element 9 and the measurement stage 3 is filled with the first liquid LQ1. With the recovery port 34, only the first liquid LQ1 can be recovered, or the first liquid LQ1 together with gas can be recovered.

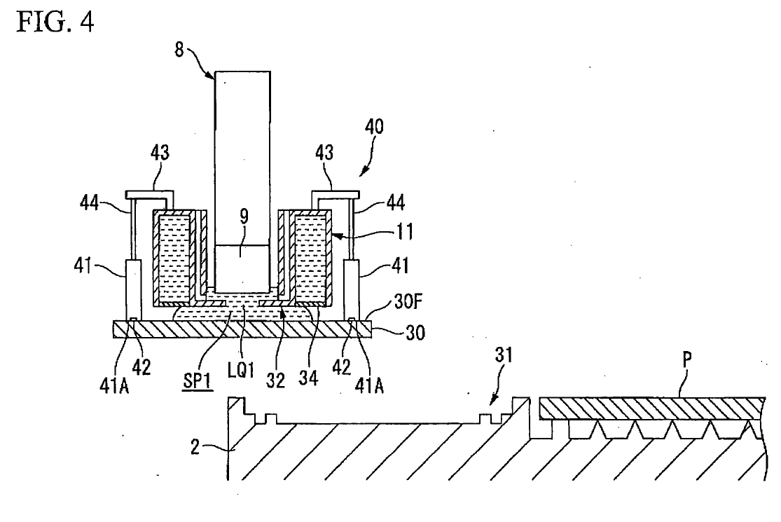

In addition, in the present embodiment, the exposure apparatus EX comprises a cap holding mechanism 40, which detachably holds the cap member 30 at the first position, which opposes the first optical element 9. FIG. 4 is a view that shows one example of the cap holding mechanism 40, which is capable of holding the cap member 30.

As shown in FIG. 4, the cap holding mechanism 40 is capable of holding the cap member 30 at the first position, which opposes the first optical element 9. When the cap holding mechanism 40 is holding the cap member 30, the first space SP1, which is capable of holding the first liquid LQ1 between the cap member 30 and the first optical element 9, is formed.

At least one part of the cap holding mechanism 40 is connected to the first nozzle member 11. In the present embodiment, the cap holding mechanism 40 uses the vacuum chuck mechanism to chuck the cap member 30. Furthermore, if the cap member 30 is formed from a magnetic body (metal), then a mechanism may be mounted to the cap holding mechanism 40 that holds the cap member 30 with magnetic force.

In the present embodiment, the cap holding mechanism 40 comprises: holding members 41, each of which has a lower surface 41A that is capable of holding au upper surface 30F of the cap member 30; and suction ports 42, which are formed in the lower surfaces 41A of the holding members 41 and chuck the cap member 30. In the present embodiment, the holding members 41 are capable of moving in the Z axial directions (the vertical directions) with respect to the first none member 11, and a plurality (for example, three) thereof is disposed on the outer side of the first nozzle member 11 (the recovery port 34). Support members 43, which correspond to the holding members 41, are provided on the upper surface of the first nozzle member 11, and drive mechanisms 44, which move the holding members 41 in the Z axial directions with respect to the support members 43, are provided between the support members 43 and the holding members 41. The cap holding mechanism 40 holds prescribed areas of the peripheral part of the upper surface 30F of the cap member 30 with the lower surfaces 41A of the holding members 41.

If the cap holding mechanism 40 is used to hold the cap member 30, which has been released from the cap holder 31, then as shown in FIG. 4, the control apparatus 7 uses the drive mechanisms 44 to dispose the lower surfaces 41A of the holding members 41 so that they are lower than (on the −Z side of) the lower surface 32 of the first nozzle member 11, and uses the suction ports 42, which are provided in the lower surfaces 41A of the holding members 41, to chuck the upper surface 30F of the cap member 30. In the cap holding mechanism 40 of the present embodiment, the cap member 30 is held by the cap holding mechanism 40 so that the lower surface 32 of the first nozzle member 11 and the upper surface 30F of the cap member 30 are spaced apart by a prescribed distance, and thereby the first space SP1 is formed between the first optical element 9 and the cap member 30. The cap member 30 may be held by the cap holding mechanism 40 so that the lower surface 32 of the first nozzle member 11 and the upper surface 30F of the cap member 30 make contact with each other.

In the present embodiment, the cap member 30 is held by using the cap holding mechanism 40 at least during the exposure of the substrate P that is held by the substrate stage 2.

In the present embodiment, when the cap member 30 is held by the cap holding mechanism 40, the control apparatus 7 performs the operation of supplying liquid via the supply port 33 of the first nozzle member 11 and the operation of recovering liquid via the recovery port 34 of the first nozzle member 11 in parallel. Thereby, the first space SP1, which is between the first optical element 9 and the cap member 30 held by the cap holding mechanism 40, is filled with the first liquid LQ1.

When the cap member 30 is held by the cap holding mechanism 40, an interface (meniscus between the first liquid LQ1 and surrounding gas is formed between lower surface of the first nozzle member 11 and the cap member 30. In addition, because the holding members 41 (the suction ports 42) of the cap holding mechanisms 40 are disposed at positions that are spaced farther apart from the first optical element 9 than from the supply port 33 and the recovery port 34 of the first nozzle member 11, the holding members 41 (the suction ports 42) and the first liquid LQ1 do not make contact.

Furthermore, the holding members 41 are connected to the first nozzle member 11 via the drive mechanism 44 and the support members 43, but they may be connected, for example, to the lens barrel PK of the projection optical system PL or a body (column) of the exposure apparatus EX that supports the lens barrel PK.

In addition, when the cap holding mechanism 40 does not hold the cap member 30—i.e., when the operation wherein the alignment system 8 detects an alignment mark on the P through the first liquid LQ1 is performed and when the operation wherein the alignment system 8 detects, for example a fiducial mark on the measurement stage 3 through the first liquid LQ1 is performed—it prevents the holding members 41 and, for example, the substrate P and the measurement stage 3 from making contact by using the drive mechanisms 44 to raise the holding members 41 so that the lower surfaces 41A thereof are positioned above (on the +Z side of) the lower surface 32 of the first nozzle member 11, as shown in FIG. 3.

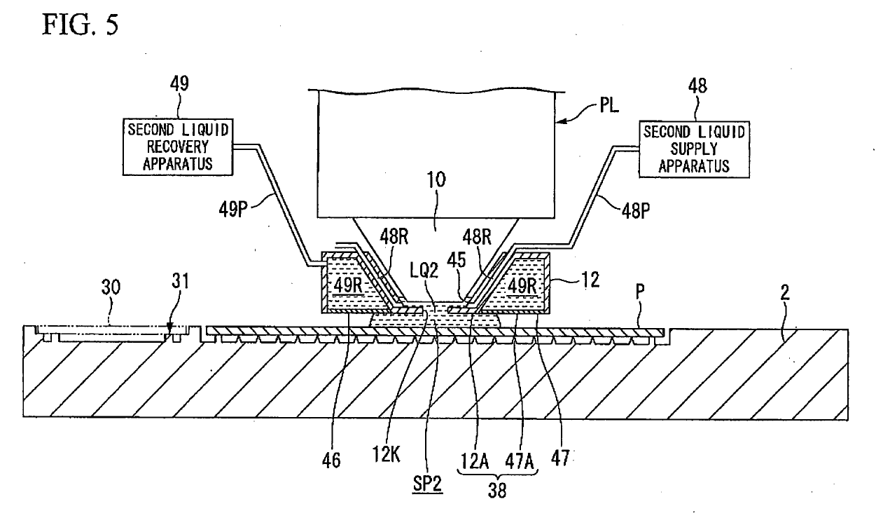

FIG. 5 is a view that shows the vicinity of the second nozzle, member 12. Furthermore, the first nozzle member 11 is not show in FIG. 5. In addition, the following explains an exemplary case wherein the substrate P is disposed at the second position, which opposes the second nozzle member 12, and the second space SP2 is formed between the second optical element 10 and the front surface of the substrate P.

The second nozzle member 12 comprises a lower surface 38 and is capable of holding the second liquid LQ2 between the lower surface 38 and the front sure of the substrate P. Holding the second liquid LQ2 between the lower surface 32 of the second nozzle member 12 and the front surface of the substrate P forms the second immersion space between the second optical element 10 and the second nozzle member 12 on one side, and the front surface of the substrate P on the other side so that second space SP2 is filled with the second liquid LQ2.

In the present embodiment, the second space SP2 includes the optical path space of the exposure light EL on the image plane side (the light emergent side) of the projection optical system PL (specifically, the optical path space of the exposure light EL between the projection optical system PL and the substrate P); in addition, when the second space SP2 is filled with the second liquid LQ2, the optical path space of the exposure light EL is also filled with the second liquid LQ2. The optical path space is the space that includes the optical path through which the exposure light EL travels.

At least while the image of the pattern of the mask M is projected to the substrate P, the exposure apparatus EX uses the second nozzle member 12 to form the second immersion space so that the second space SP2 is filled with the second liquid LQ2, and irradiates the substrate P, which is held by the substrate stage 2, with the exposure light EL from the mask M, through the projection optical system PL and the second liquid LQ2. The exposure light EL is emitted from the second optical element 10 of the projection optical system PL is irradiated onto the surface P through the second liquid LQ2. Thereby, the image of the pattern of the mask M is projected onto the substrate P, which is thereby exposed.

In the present embodiment the exposure apparatus EX adopts a local liquid immersion system wherein the second immersion space is formed between the second nozzle member 12 and the substrate P so that part of the area on the substrate P that includes the projection area of the projection optical system PL is covered with the second liquid LQ2.

The second nozzle member 12 comprises a supply port 45, which is capable of supplying the second liquid LQ2, and a recovery port 46, which is capable of recovering the second liquid LQ2. The supply port 45 is capable of supplying the second liquid LQ2 to the second space SP2. In the present embodiment a porous member (mesh) 47 is disposed in the recovery port 46. In the embodiment, the porous member 47 includes a plate on which a plurality of circular hoes (trough holes) are provided. However, as the porous member 47, a sintered member in which a plurality of pores are formed (for example, a sintered metal), foam member (for example, a foam metal), or the like may be used. The second nozzle member 12 comprises an opening 12K wherethrough the exposure light EL passes. The lower surface 38 of the second nozzle member 12 comprises a flat surface 12A, which is disposed so that it surrounds the opening 12K, and a lower surface 47A (the recovery port 46) of the porous member 47 that is disposed around the flat surface 12A.

The supply port 45 is connected to a second liquid supply apparatus 48, which is capable of feeding the second liquid LQ2 through a supply pipe 48P and a supply passageway 48R, which is formed inside the second nose member 12. The recovery port 46 is connected to a second liquid recovery apparatus 49 that is capable of recovering at least the second liquid LQ2 through a recovery passageway 49R, which is formed inside the second nozzle member 12, and a recovery pipe 49P.

The second liquid supply apparatus 48 is capable of feeding the second liquid LQ2, which is pure and temperature adjusted. In addition, the second liquid recovery apparatus 49 comprises, for example, a vacuum system, and is capable of recovering the second liquid LQ2 trough the recovery port 46. The control apparatus 7 controls the operation of the second liquid supply apparatus 48 ad the second liquid recovery apparatus 49. After the second liquid LQ2, which is fed from the second liquid supply apparatus 48, flows trough the supply pipe 4 and fire supply passageway 48R of the second nozzle member 12, it is supplied to the second space SP2, which includes the optical path space of the exposure light EL, via the supply port 45. In addition, after the second liquid LQ2, which is recovered via the recovery port 46 by driving the second liquid recovery ads 49, flows through the recovery passageway 49R of the second nozzle member 12, it is recovered by the second liquid recovery apparatus 49 through the recovery pipe 49P. The control apparatus 7 performs the operation of supplying liquid via the supply port 45 and the operation of recovering liquid via the recovery port 46 in parallel; thereby, the second immersion space of the second liquid LQ2 is formed so that the second space SP2 between the second optical element 10 and the substrate P is filled with the second liquid LQ2.

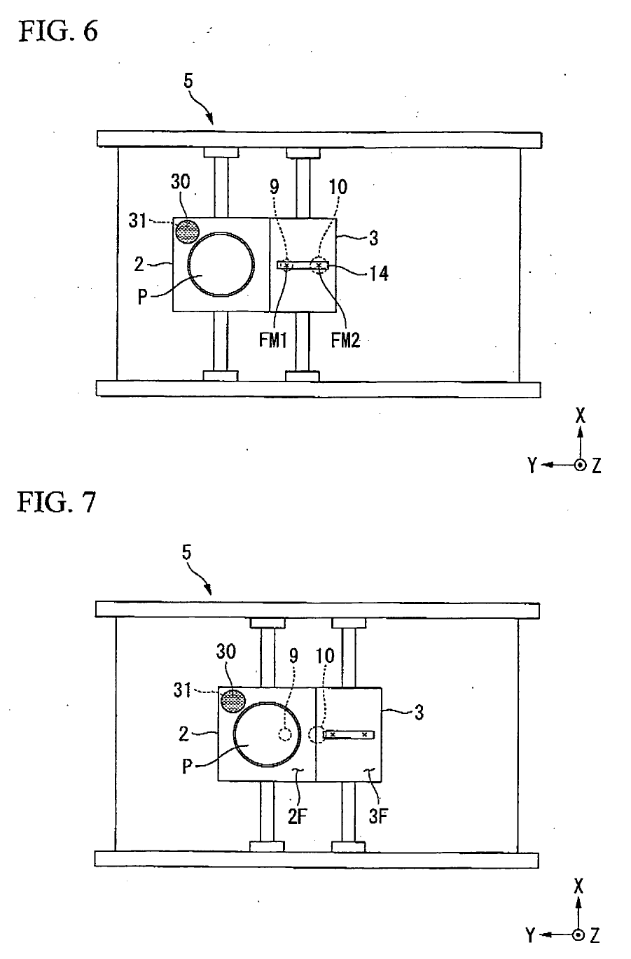

One example of the operation of the exposure apparatus EX that has the configuration discussed above will now be explained, referencing FIG. 6 through FIG. 13.

The control apparatus 7 moves the substrate stage 2 to the substrate exchange position RP and uses the transport system H to load the substrate P to be exposure processed onto the substrate stage 2. The substrate P is held by the substrate stage 2. In addition, as shown in FIG. 6, the control apparatus 7 uses the drive system 5 to move the measurement stage 3 to the positions that oppose the first optical element 9 (the first nozzle member 11) and the second optical element 10 (the second nozzle member 12), thereby forming: the first space SP1, which is capable of holding the first liquid LQ1, between the first optical element 9 and the measurement stage 3; as well as the second space SP2, which is capable of holding the second liquid LQ2, between the second optical element 10 and the measurement stage 3. Furthermore, the control apparatus 7 uses the first nozzle member 11 to form the first immersion space and also uses the second nozzle member 12 to form the second immersion space. Thereby, the first liquid LQ1 is held in the first space SP1 and the second liquid LQ2 is held in the second space SP2.

After the first immersion space and the second immersion space are formed, the control apparatus 7 uses the instrument (the measuring member) that is mounted to the measurement stage 3 to start a measurement operation. For example, the control apparatus 7 starts the operation that acquires baseline formation. As shown in FIG. 6, when the baseline information is acquired, the cap member 30 is held by the cap holder 31 of the substrate stage 2.

The control apparatus 7 stars the operation that detects an alignment mark on the substrate P and the fiducial mark FM1 on the measurement stage 3 through the alignment system 8, which includes the first optical element 9, and the first liquid LQ1.

Specifically, as shown in FIG. 6, in a state wherein the measurement sage 3 is disposed at the first position, which opposes the first optical element 9, the control apparatus 7 uses the alignment system 8 to detect the first fiducial mark FM1 on the measurement stage 3 through the first liquid LQ1 while using the measurement system 6 to measure the positional information of the measurement stage 3 in the X and Y directions. Thereby, the positional relationship between the detection reference position of the alignment system 8 and the first fiducial mark FM1 is detected.

In addition, in a state wherein the measurement stage 3 is disposed at the second position, which opposes the second optical element 10, the control apparatus 7 uses the alignment system 13 to detect the second fiducial mark FM2 on the measurement stage 3 and the corresponding alignment mark on the mask M while using the measurement system 6 to measure the positional information of the measurement stage 3 in the X and Y directions. The alignment system 13 detects the second fiducial mark FW through the projection optical system PL, which includes the second optical element 10, and the second liquid LQ2. Thereby, the positional relationship between the second fiducial mark FM2 and the corresponding alignment mark on the mask M is detected.

In the present embodiment, the operation of detecting the first fiducial mark FM1 by the alignment system 8 and the operation of detecting the second fiducial mark FM2 by the alignment system 13 are performed synchronously, but they may be performed asynchronously. For example, after one of the detection operations, i.e., either the operation of detecting the first fiducial mark FM1 by the alignment system 8 or the operation of detecting the second fiducial mark FM2 by the alignment system 13, is performed, the other detection operation may be performed after the measurement stage 3 is moved while using the measurement system 6 to measure the positional information of the measurement stage 3 in the X and Y directions.

Furthermore, the control apparatus 7 derives the distance (the positional relationship), i.e., the baseline information of the alignment system 8, within the coordinate system defined by the measurement system 6 between the detection reference position of the alignment system 8 and the projection position (the center of projection) of the mask M pattern image, which is formed by the projection optical system PL, based on the positional relationships between: the detection reference position of the alignment system 8 and the first fiducial mark FM1; the second fiducial mark M and the corresponding alignment mark on the mask M; and the first fiducial mark FM1 and the second fiducial mark FM2, which is known.

The measurement operation that uses the measurement stage 3 is not limited to baseline measurement and may include, fox example, a measurement operation that uses the aerial image measuring sensor discussed above. If a measurement operation that uses the aerial image sensor is performed, then the control apparatus 7 irradiates at least part of the aerial image measuring sensor, which is disposed in the measurement stage 3, with the exposure light EL through the projection optical system PL and the second liquid LQ2. The aerial image measuring sensor receives the exposure lift EL through the projection optical system PL and the second liquid LQ2 and measures the imaging characteristics of the projection optical system PL. Similarly, a measurement process is performed that uses, for example, a nonuniformity sensor, an irradiance sensor, or a wavefront aberration measuring instrument, as needed. The nonuniformity sensor, the irradiance sensor, the wavefront aberration measuring instrument, and the like also perform measurement through the projection optical system PL and the second liquid LQ2. Based on these measurement results, various adjustments are made in order to expose a subsequent substrate P.

Furthermore, in the present embodiment, after the substrate P is held by the substrate stage 2 at the substrate exchange position RP, the control apparatus 7 performs a measurement operation in a state wherein the linear edge on the −Y side of the upper surface 2F of the substrate stage 2 and the linear edge on the +Y side of the upper surface 3F of the measurement stage 3 are brought into close proximity or contact, and wherein the upper surface 2F and the upper surface 3F form a substantially continuous surface, as shown in FIG. 6. Thereby, when the upper surface 3F moves away from the first position by movement of the measurement stage 3 in the −Y direction, there is the upper surface 2F of the substrate stage 2 at the first position, and then the first space SP1 continues to be formed between the first optical element 9 and the first nozzle member 11 on one side and the upper surface 2F on the other side. That is, during the measuring operation, the first liquid LQ1 can continue to be held below the first optical element 9. The substrate stage 2 and the measurement stage 3 may be spaced apart during at least a part of the measuring operation. If the upper surface 3F of the measurement stage 3 does not move away from the first position during at least a part of the measurement operation, the substrate stage 2 and the measurement stage 3 may be spaced apart. For example, at least part of a measurement operation that uses the measurement stage 3 may be performed during the operation of exchanging the substrate P between the substrate stage 2 and the transport system H.

Next, the control apparatus 7 controls the drive system 5 so as to move the substrate stage 2 (the substrate P) to the first position, which opposes the first optical element 9, in order to use the alignment system 8 to detect an alignment mark on the substrate P.

The exposure apparatus EX of the present embodiment is capable of moving at least one of the first immersion space (the immersion region of the first liquid LQ1) and the second immersion space (the immersion region of the second liquid LQ2) between the upper surface 2F of the substrate stage 2 and the upper surface 3F of the measurement stage 3 by synchronously moving the substrate stage 2 and the measurement stage 3 in the X and Y directions with respect to the first and second optical elements 9, 10 within the prescribed area that includes the first position and the second position in a state wherein the linear edge on the −Y side of the upper surface 2F of the substrate stage 2 and the linear edge on the +Y side of the upper surface 3F of the measurement stage 3 are brought into close proximity or contact and wherein the upper surface 2F and the upper surface 3F form a substantially continuous surface, as disclosed in, for example, PCT International Publication No. WO2005/074014 (corresponding European Patent Application, Publication No. 1,713,113A).

In a state wherein the first immersion space is formed so that the alignment system 8 can detect an alignment mark on the substrate P through the first liquid LQ1, the control apparatus 7 moves the substrate stage 2 and the measurement stage 3 so that the first optical element 9 of the alignment system 8 and the substrate P are opposed. Disposing the substrate stage 2 (the substrate P) at the first position maintains the first space SP1, which is capable of holding the first liquid LQ1, between the first optical element 9 and the substrate stage 2 (the skate P). The first space SP1 is filled with the first liquid LQ1 of the first immersion space.

At this time, at least one of the substrate stage 2 and the measurement stage 3 is also disposed at the second position, which opposes the second optical element 10 of the projection optical system PL, and thereby the second spare SP2, which is capable of holding the second liquid LQ2, is maintained between the second optical element 10 and at least one of the substrate stage 2 and the measurement stage 3. The second space SP2 is filled with the second liquid LQ2 of the second immersion space. Furthermore, as shown in FIG. 7, in the present embodiment, in the alignment system 8 is used to detect an alignment mark on the substrate P, the measurement stage 3 is moved together with the substrate stage 2 while the state wherein the substrate stage 2 and the measurement stage 3 are brought into close proximity or contact is maintained; however, if the first space SP1 that is filled with the first liquid LQ1 can be maintained between the second optical element 10 and the substrate stage 2 (the substrate P) while the detection of the alignment mark on the substrate P is underway, then the measurement stage 3 may be retracted to a prescribed position that is spaced apart from the substrate stage 2.

As shown in FIG. 7, in a state wherein the first optical element 9 of the alignment system 8 and the substrate P are opposed, the control apparatus 7 uses the alignment system 8 to detect an alignment mark on the substrate P. The alignment system 8 detects the alignment mark on the substrate P through the first liquid LQ1.

A plural of alignment marks are formed on the substrate P sot they correspond to a plurality of shot regions on the substrate P. The control apparatus 7 uses the alignment system 8 to measure a prescribed number of alignment marks on the substrate P while using the measurement system 6 to measure the positional information of the substrate stage 2. The control apparatus 7 uses an arithmetic process to derive positional information for each shot region of the plurality of shot regions on the substrate P with respect to the detection reference position of the alignment system 8 based on positional information about each alignment mark on the substrate P.

The control apparatus 7 determines the positional coordinates (the array coordinates) of each shot region of the plurality of shot regions on the substrate P within the XY coordinate system defined by the measurement system 6 based on the results of detecting the alignment marks on the substrate P by the alignment system 8.

The control apparatus 7 derives the positional relationship between each of the shot regions on the substrate P and the projection position of the image of the pattern of the mask M within the coordinate system defined by the measurement system 6 based on the baseline information and on the positional relationship between the detection reference position of the alignment system 8 and each of the shot regions on the substrate P (the array information of each shot region with respect to the detection reference position) within the coordinate system defined by the measurement system 6.

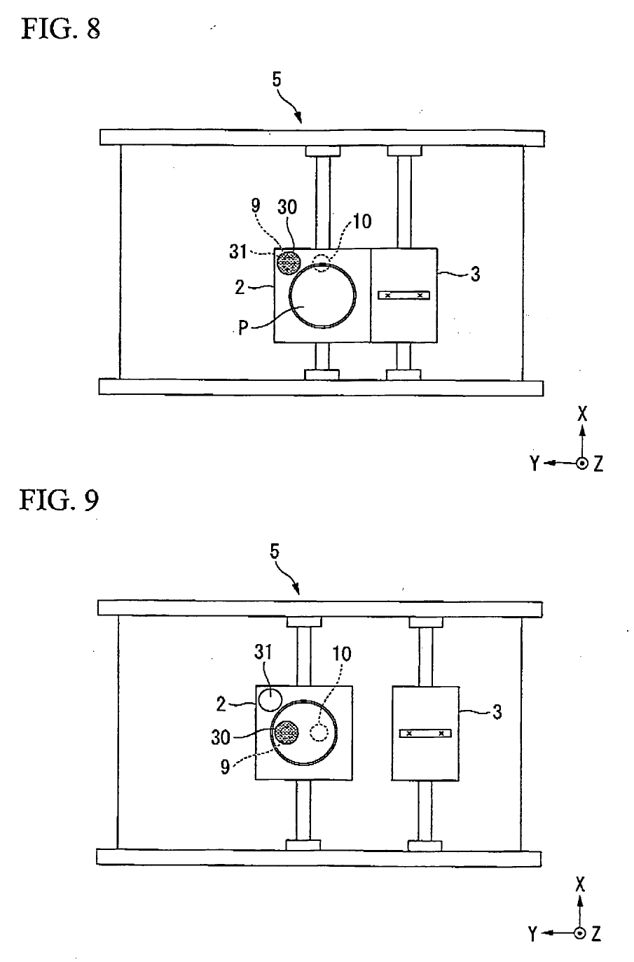

Next as shown in FIG. 8, while the state wherein the first immersion space is formed is maintained, the control apparatus 7 controls the drive system 5 so as to move the substrate stage 2 so that the cap member 30, which is held by the cap holder 31 of the substrate stage 2, moves to the first position. Thereby, the first optical element 9 and the cap member 30, which is held by the cap holder 31, are opposed. The first space SP1 is formed between the first optical element 9 and the cap member 30 and the first liquid LQ1 is held therein.

The control apparatus 7 brings the upper surface 30F of the cap member 30, which is held by the cap holder 31, and the lower surfaces 41A of the holding members 41 into contact by using the drive mechanisms 44 to lower the holding members 41 of the cap holding mechanism 40 while the state wherein the first immersion space is formed is maintained. Furthermore, the control apparatus 7 performs a suction operation, which uses the suction ports 42 that are formed in the lower surfaces 41A of the holding members 41, in order to chuck the upper surface 30F of the cap member 30 via the lower surfaces 41A of the holding members 41, and releases the hold of the cap member 30 by the cap holder 31. Furthermore, the control apparatus 7 raises the holding members 41, which chuck the cap member 30, by controlling the drive mechanism 44 of the cap holding mechanism 40, and release the cap member 30 from the cap holder 31. Thereby, in a state wherein the first space SP1, which is filled with the first liquid LQ1, is maintained between the cap member 30 and the first optical element 9, the substrate stage 2 can move freely. For example, the substrate stage 2 can move to a position where the surface of the substrate P and the upper surface 2F do not oppose the first optical element 9.

Even during the operation that transfers the cap member 30 from the cap holder 31 to the cap holding mechanism 40, at least one of the substrate stage 2 and the measurement stage 3 is disposed at the second position, which opposes the second optical element 10 of the projection optical system PL, and the second space SP2, which is filled with the second liquid LQ2, is maintained.

Furthermore, as shown in FIG. 9, in a state wherein the cap member 30 is held by the cap holding mechanism 40 and the first space SP1 is filled with the first liquid LQ1 the control apparatus 7 moves the substrate stage 2 (the substrate P) to the second position, which opposes the second optical element 10 of the projection optical system PL, and starts the exposure of each shot region on the substrate P.

The control apparatus 7 exposes the substrate P by radiating the exposure light EL through the projection optical system PL and the second liquid LQ2 onto the substrate P. During the exposure of the substrate P, the cap member 30 is held by the cap holding mechanism 40 and is disposed at the first position, and the first space SP1 is filled with the first liquid LQ1. In addition, as shown in FIG. 9, during the exposure of the substrate P, which is held by the substrate stage 2, the measurement stage 3 moves to a prescribed retracted position, which is spaced apart from the substrate stage 2.

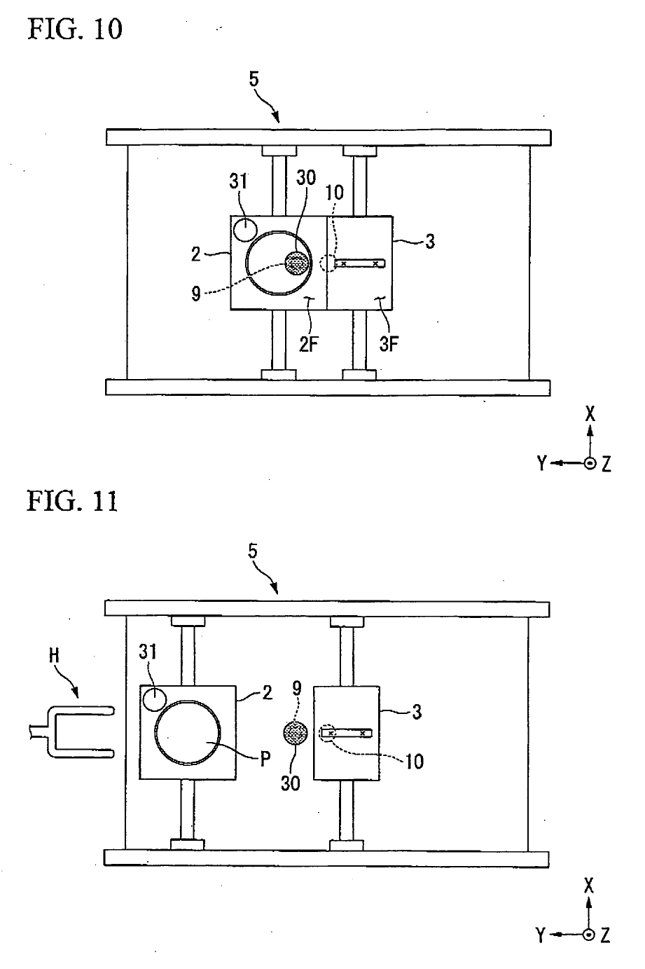

As shown in FIG. 10, after the exposure of the substrate P is complete and in a state wherein the upper surface 2F of the substrate stage 2 and the upper surface 3F of the measurement stage 3 are brought into close proximity or contact as described above, the control apparatus 7 synchronously moves the substrate stage 2 and the measurement stage 3 in the X and Y directions with respect to the second optical element 10 (the second nozzle member 12) so as to dispose the measurement stage 3 at the second position which opposes the second optical element 10 (the second nozzle member 12), while maintaining the state wherein the second immersion space is formed. Thereby, the second space SP2, which is filled with the second liquid LQ2, is maintained between the second optical element 10 and the measurement stage 3.

Furthermore, as shown in FIG. 11, the control apparatus 7 moves the substrate stage 2, which holds the exposure completed substrate P, to the prescribed substrate exchange position RP, and unloads the exposure completed substrate P from the substrate stage 2 and loads the substrate P to be exposed onto the substrate stage 2. In addition, during the substrate exchange operation at the substrate exchange position RP, as needed, the measurement operation, which uses the measurement stage 3, through the second liquid LQ2 of the second immersion space and adjustments for the exposure of the subsequent substrate P are executed. At this time as well, the first space SP1, which is filled with the first liquid LQ1, is maintained between the first optical element 9 of the alignment system 8 and the cap member 30.

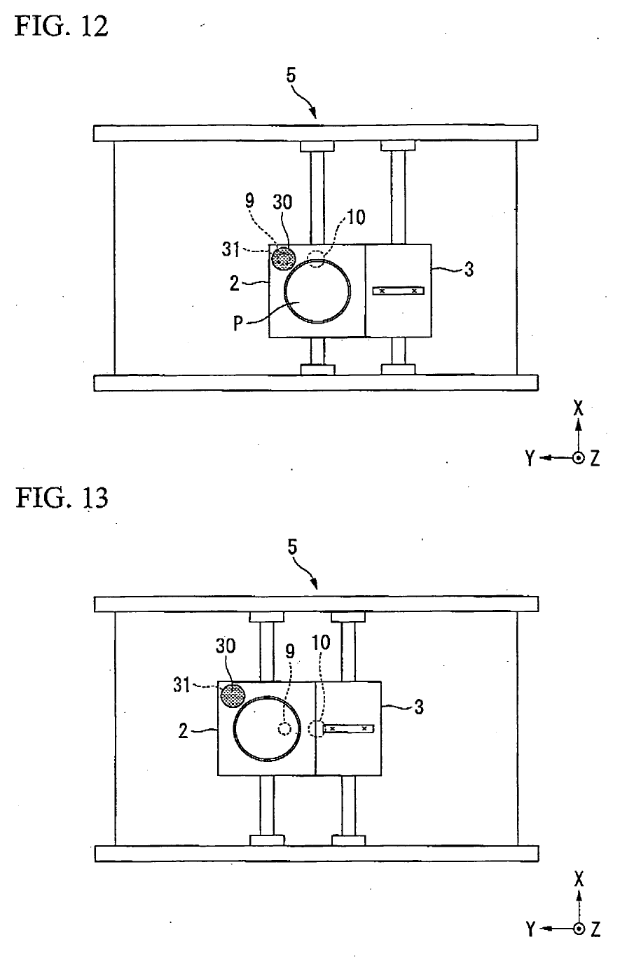

After the substrate P is loaded onto the subsume stage 2, similar to that discussed above, the control apparatus 7 synchronously moves the substrate stage 2 and the measurement stage 3 in the X and Y directions in a state wherein the upper surface 2F of the substrate stage 2 and the upper surface 3F of the measurement stage 3 are brought into close proximity or contact and, as shown in FIG. 12, causes the cap member 30, which is held by the cap holding mechanism 40, and the cap holder 31 of the substrate stage 2 to oppose one another.

Furthermore, the cap member 30 is mounted on the cap holder 31 by using the drive mechanisms 44 to lower the holding members 41 of the cap holding mechanism 40, which holds the cap member 30, while maintaining the state wherein the first immersion space is formed. Furthermore, the control apparatus 7 stops the suction operation that uses the suction ports 42, which are formed in the lower surfaces 41A of the holding members 41, and uses the tap holder 31 to chuck the cap member 30. Furthermore, the control apparatus 7 controls the drive mechanisms 44 of the cap holding mechanism 40 so as to se the holding members 41. Thereby, the cap member 30 is held by the cap holder 31 so that it is spaced apart from the cap holding mechanism 40.

Furthermore, as shown in FIG. 13, in order to start the operation that acquires positional information about the substrate P through the first liquid LQ1, the control apparatus 7 controls the drive system 5 so as to move the substrate P to the first position, which opposes the first optical element 9, and, similar to the operation that was explained referencing FIG. 7 and the like, performs the operation that detects an alignment mark on the substrate P and performs arithmetic processing. At this time, at least one of the substrate stage 2 and the measurement stage 3 is disposed at the second position, which opposes the second optical element 10 of the projection optical system PL, and the second space SP2, which is capable of holding the second liquid LQ2, is maintained between the second optical element 10 and at least one of the substrate stage 2 and the measurement stage 3.

Furthermore, similar to that discussed above, after the control apparatus 7 acquires positional information about the substrate P, it uses the cap holding mechanism 40 to hold the cap member 30 at the first position and then starts the exposure of the substrate P while maintaining the first space SP1, which is filled with the first liquid LQ1, between the first optical element 9 of the alignment system 8 and the cap member 30.

The control apparatus 7 performs these operations repetitively, and thereby exposes a plurality of the substrates P successively while maintaining the first space SP1, which is filled with the first liquid LQ1, and the second space SP2, which is filled with the second liquid LQ2.

Furthermore, in the present embodiment, the control apparatus 7 continues the operation wherein the operation of supplying liquid via the supply port 33 of the first nozzle member 11 and the operation of recovering the liquid via the recovery port 34 of the first nozzle member 11 are performed in parallel while at least one of the measurement stage 3, the substrate stage 2, the substrate P held by the substrate stage 2, and the cap member 30 is disposed at the first position, which opposes the first optical element 9. Thereby, the first space SP1 continues to be filed with the pure first liquid LQ1, which is continuously supplied via the supply port 33.

As explained above, in the present embodiment, because neither the operation that recovers all of the first liquid LQ1 nor the operation that stops the supply of the first liquid LQ1 has to be performed, it is possible to prevent, for example, a decrease in the throughput of the exposure apparatus EX or deterioration of the first optical element 9, and thereby to use the alignment system 8, which includes the first optical element 9, to acquire positional information about the substrate P accurately. Accordingly, the substrate P can be exposed satisfactorily and efficiently.

In addition, in a case where all of the first liquid LQ1 has been recovered, when the operation of supplying the first liquid LQ1 resumes there is a possibility that a waiting time will need to be set that extends until the state (such as the temperature) of the first liquid LQ1 to be supplied stabilizes. In this case, there is a problem in that the throughput of the exposure apparatus EX decreases. In addition, if all of the first liquid LQ1 is recovered and the front surface of the first optical element 9 that contacts the first liquid LQ1 changes from the wet state to the dry state, then the vaporization of the first liquid LQ1 that remains on the suds of the first optical element 9 causes, for example, residue of the liquid (a watermark) to form on the surface of the first optical element 9 and the temperature of the first optical element 9 to age, and therefore there is a possibility that the performance of the first optical element 9 will degrade.

In the present embodiment, it is possible to continue filling the first space SP1, which is capable of holding the first liquid LQ1, between the first optical element 9 and at least one of the substrate stage 2, the substrate P held by the substrate stage 2, the measurement stage 3, and the cap member 30, and therefore it is possible to maintain the state wherein the first liquid LQ1 contacts the first optical element 9. Accordingly, it is possible to prevent the occurrence of the problems discussed above, and thereby to use the first optical element 9 to acquire positional information about the substrate P accurately, and to expose the substrate P satisfactorily and efficiently.

In addition, in the present embodiment, there is no need to perform the operation that recovers all of the second liquid LQ2 and the operation that stops the supply of the second liquid LQ2. Accordingly, it is possible to prevent, for example, a decrease in the throughput of the exposure apparatus EX and deterioration of the second optical element 10, and thereby to use the projection optical system PL, which includes the second optical element 10, to expose the substrate P satisfactorily and efficiently.

Furthermore, in the present embodiment, the operation of supplying liquid via the supply port 33 of the first nozzle member 11 and the operation of recovering liquid via the recovery port 34 of the first nozzle member 11 continue while at least one of the measurement stage 3, the substrate stage 2, the substrate P held by the substrate stage 2, and the cap member 30 is disposed at the first position, which opposes the first optical element 9; however, the operation of supplying liquid via the supply port 33 and the operation of recovering liquid via the recovery port 34 may be stopped at a prescribed time, such as when the cap member 30 is held by the cap holding mechanism 40, while maintaining the first space SP1, which is filled with the first liquid LQ1. In addition, the first liquid LQ1 may be removed from the first space SP1 between the first optical element 9 and the cap member 30 as needed. For example, the first liquid LQ1 may be removed from the first space SP when the exposure apparatus EX is stopped in a state wherein the cap member 30 is held by the cap holding mechanism 40. Furthermore, the cap holding mechanism 40 may hold the cap member 30 so that the upper surface 30F of the cap member 30 and the lower surface 41A of the holding member 41 do not make contact with each other. In the embodiment, when one of the cap holding mechanism 40 and the cap holder 31 holds the cap member 30, which is released from the other one, only the holding member 41 moves along the Z directions, however, only the substrate stage 2 may move along the Z directions, or both the holding member 41 and the substrate stage 2 may move along the Z directions.

### Second Embodiment

The following explains a second embodiment. In the explanation below, constituent parts that are identical or equivalent to those in the embodiment discussed above are assigned identical symbols, and the explanations thereof are therefore abbreviated or omitted.

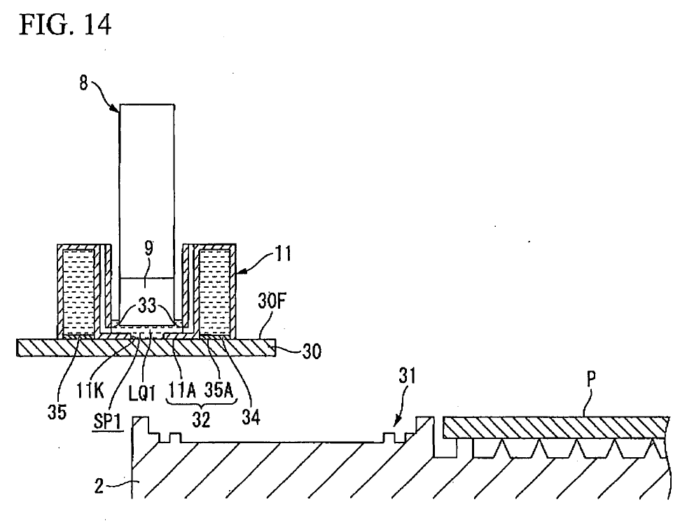

FIG. 14 shows part of the exposure apparatus EX according to the second embodiment. In the first embodiment discussed above, the exposure apparatus EX comprises the cap holding mechanism 40, which has the holding members 41 that hold the cap member 30 at the first position; however, a characteristic portion of the second embodiment is that the cap member 30 is held at the first position by the recovery port 34 of the first nozzle member 11.

After the operation that uses the alignment system 8 to acquire positional information about the substrate P is complete, the control apparatus 7 moves the substrate stage 2 so as to dispose the cap member 30, which is held by the cap holder 31, at the first position, which opposes the first optical element 9, while maintaining the state wherein the first immersion space is formed by performing the operation of supplying the liquid via the supply port 33 of the first nozzle member 11 and the operation of recovering the liquid via the recovery port 34 of the first nozzle member 11 in parallel. Thereby, the first space SP1 is formed between the first optical element 9 (the first nozzle member 11) and the cap member 30.

After the first space SP1 is formed between the first optical element 9 (the first nozzle member 11) and the cap member 30, the control apparatus 7 stops the operation of supplying liquid via the supply port 33 of the first nozzle member 11 and adjusts the positional relationship between the first nozzle member 11 and the cap member 30 in the Z axial directions so as to bring the lower surface 32 of the first nozzle member 11 and the upper surface 30F of the cap member 30 into contact. Specifically, the control apparatus 7 raises the substrate stage 2, which holds the cap member 30, in the +Z direction, and thereby brings the lower surface 32 of the first nozzle member 11 and the upper surface 30F of the cap member 30 into contact.

The recovery port 34 is provided in the lower surface 32 of the first nozzle member 11, which opposes the upper surface 30F of the cap member 30, and therefore the control apparatus 7 can chuck the cap member 30 to the lower surfs 32 of the first nozzle member 11 by performing the recovery operation (the suction option) via the recovery port 34. The control apparatus 7 uses the recovery port 34 to hold the cap member 30 to the lower surface 32 of the first nozzle member 11 so that the first space SP1, which is capable of holding the first liquid LQ1, is formed between the first optic element 9 and the cap member 30.

In the present embodiment, the lower surface 35A of the porous member 35, which is disposed in the recovery port 34, is substantially flat, and the flat surface 11A of the first nozzle member 11 is substantially flush therewith. The control apparatus 7 can close the opening 11K by using the recovery port 34 of the first nozzle member 11 to chuck the cap member 30. Furthermore, holding the cap member 30 with the lower surface 32 of the first nozzle member 11 so that the opening 11K is closed makes it possible to form the first space SP1, which is capable of holding the first liquid LQ1, between the first optical element 9 and the cap member 30.

After the cap member 30 is held to the lower surface 32 of the first nozzle member 11, the control apparatus 7 releases the hold of the cap member 30 by the cap holder 31 of the substrate stage 2.

In the present embodiment, in the state wherein the cap member 30 is held by the recovery port 34 of the first nozzle member 11, the control apparatus 7 stops the operation of supplying liquid via the supply port 33 of the first nozzle member 11. In the state wherein the cap member 30 contacts the lower surface 32 of the first nozzle member 11, even though the operation of supplying liquid via the supply port 33 of the first nozzle member 11 is stopped, virtually none of the first liquid LQ1 is recovered via the recovery port 34, and it is therefore possible to continue filling the first space SP1 with the first liquid LQ1 and to continue making the first liquid LQ1 and the first optical element 9 contact one another. Furthermore, the first liquid LQ1 may be removed from the space between the first optical element 9 and the cap member 30 as needed.

Furthermore, for example, if a plurality of supply ports 33 is formed, then, in the state wherein the recovery port 34 of the first nozzle member 11 is used to chuck the cap member 30, it is possible to make some of the supply ports 33 function as suction ports and to supply the first liquid LQ1 to the first space SP1 via some of the supply ports 33, and to suction (recover) the first liquid LQ1 from the first space SP1 via other supply ports 33 (suction ports). Thereby, the first space SP1 is filled with the pure first liquid LQ1, which is supplied continuously via the supply ports 33.

Furthermore, in the first and second embodiments discussed above, the measuring instrument may be mounted to the cap member 30. In this case, the cap member 30, which is held by the cap holding mechanism 40, can be disposed at the first position, and measurements can be performed using that measuring instrument of the cap member 30. In addition, a transmitting apparatus may be provided to the cap member 30 that wirelessly transmits the measuring instruments measurement results, which may be wirelessly transmitted to the control apparatus 7 (or to a receiving apparatus that is connected to the control apparatus 7).

Furthermore, the first and second embodiments explained an exemplary case wherein there is one first optical element 9 (alignment system 8), however a plurality of first optical elements 9 (alignment systems 8) may be provided so that a plurality of marks can be detected substantially at the same time. If a plurality of the first optical elements 9 is provided, then the first nozzle member 11 may be formed with a structure that is in accordance with the plurality of the first optical elements 9 so that first spaces SP1 can be formed that correspond to the ply of the first optical elements 9. In this case, the cap member 30 is also formed with a that is in accordance with the plurality of the first optical elements 9. For example, a single cap member may be held at a position that opposes the plurality of first optical elements, or multiple cap members may be held at positions that oppose the multiple first optical elements.

### Third Embodiment

The following explains a id embodiment. In the explanation below, constituent parts that are identical or equivalent to those in the embodiments discussed above are assigned identical symbols, and the explanations thereof are therefore abbreviated or omitted.

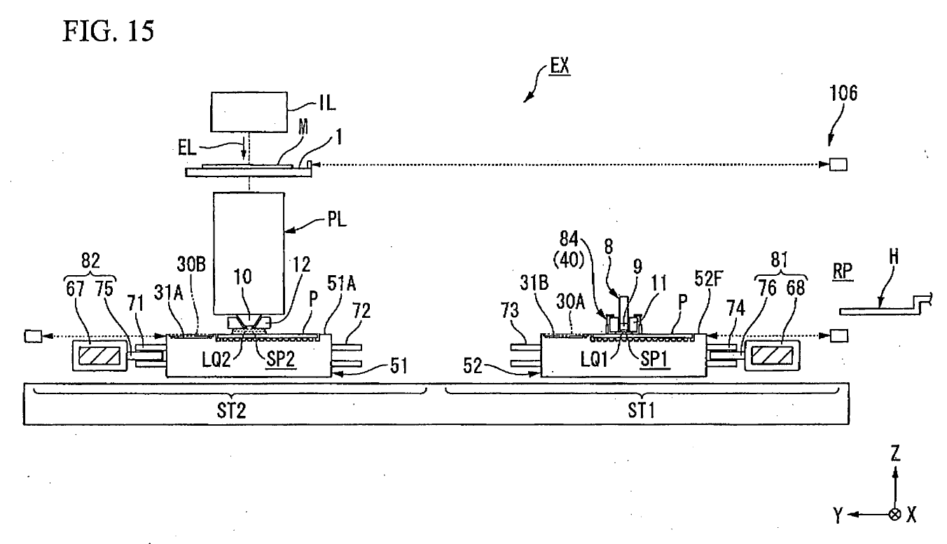

FIG. 15 is a schematic block diagram that shows an exposure apparatus EX according to the third embodiment. The present embodiment explains an exemplary case wherein the exposure apparatus EX is a multi-stage type (a twin stage type) exposure apparatus that comprises multiple (two) of substrate stages, each of which is capable of moving while holding the substrate P, as disclosed in, for example, Japanese Patent Application, Publication No. H10-163099A, Japanese Patent Application, Publication No. H10-214783A (corresponding U.S. Pat. Nos. 6,341,007, 6,400,441, 6,549,269, and 6,590,634), Published Japanese Translation No. 2000-505958 of the PCT International Publication (corresponding U.S. Pat. No. 5,969,441), Published Japanese Translation No. 2000-511704 of the PCT International Publication, Published Japanese Translation No. 2001-513267 of the PCT International Publication, Japanese Patent Application, Publication No. 2002-158168A, U.S. Pat. No. 6,341,007, U.S. Pat. No. 6,262,796, and U.S. Pat. No. 6,208,407. In the present embodiment, the exposure apparatus EX comprises a first substrate stage 51, which is capable of holding and moving the substrate P, and a second substrate stage 52, which is capable of holding and moving the substrate P independently of the first substrate stage 51, and successively exposes a plurality of substrates P while alternating between the first substrate stage 51 and the second substrate stage 52, as disclosed in the abovementioned U.S. Pat. No. 6,262,796.

In the present embodiment, the exposure apparatus EX comprises a measurement station ST1, which performs a prescribed measurement with respect to the exposure and exchanges the substrate P, and an exposure station ST2, which irradiates the substrate P with the exposure light EL. Both the first substrate stage 51 and the second substrate stage 52 are capable of holding the substrate P and moving between the measurement station ST1 and the exposure station ST2

Various measuring apparatuses, such as the focus leveling detection system and the alignment system 8 (including the first optical element 9 for aging positional information about the substrate P), that are capable of performing measurement with respect to the exposure of the substrate P are disposed in the measurement station ST1. In addition, the first nozzle member 11, which is capable of forming the first immersion space so that the first space SP1 formed between the first optical element 9 and the object disposed at the first position opposing the first optical element 9 is filled with the first liquid LQ1, is disposed in the measurement station ST1.

The illumination system IL, the mask stage 1, which is capable of holding and moving the mask M, and the projection optical system PL, which includes the second optical element 10 that emits the exposure light EL, are disposed in the exposure station ST2. In addition, the second nozzle member 12, which is capable of forming the second immersion space so that the second space SP2 formed between the second optical element 10 and the object disposed at them second position opposing the second optical element 10 is filled with the second liquid LQ2, is disposed in the exposure station ST2.

Both the first substrate stage 51 and the second substrate stage 52 are capable of holding the substrate P and moving within a prescribed area on the base member BP that includes the first position, which opposes the first optical element 9 that is disposed in the measurement station ST1, and the second position, which opposes the second optical element 10 that is disposed in the exposure station ST2.

In the present embodiment, the objects that are capable of opposing the first optical element 9 and the second optical element 10, i.e., the objects that are capable of being disposed at (capable of moving to) the first position and the second position, include the first substrate stage 51 and the second substrate sage 52, which are capable of moving on the light emergent side of the projection optical system PL. In addition, the objects that are capable of being disposed at (capable of moving to) the first position and the second position include a first cap member 30A and a second cap member 30B, which are discussed later. Furthermore, the substrate P that is held by the first substrate stage 51 and the substrate P that is held by the second substrate stage 52 are capable of being disposed at the first position and the second position.

The first substrate stage 51 and the second substrate stage 52 have substantially the same shape, size, and configuration. In the present embodiment, each of the first and second substrate stages 51, 52 has the same basic configuration as the substrate stage 2 that was explained in the first and second embodiments discussed above, but at least part of the measuring instrument (the measuring member) that is held by the measurement stage 3, which was explained in the first and second embodiments discussed above, is disposed in at least one of the first and second substrate stages 51, 52.

A drive system 105 comprises actuators, such as liner motors, and the first substrate stage 51 and the second substrate stage 52 are each capable of moving with six degrees of freedom, i.e., in the X, Y, and Z axial directions and the θX, θY, and θZ directions.

A measurement system 106 is capable of measuring the positional information of the it and second substrate stages 51, 52 and, similar to the embodiments discussed above, comprises laser interferometers. In addition, although not shown, the measurement system 106 of the present embodiment comprises laser interferometers (Z interferometers) that are capable of mea the positional information of the first and second substrate stages 51, 52 in the Z axial directions, as disclosed in, for example, Japanese Patent Application, Publication No. 2000-323404A, Published Japanese Translation No. 2001-513267 of the PCT International Publication, and U.S. Pat. No. 6,208,407. Based on the measurement results of the measurement system 106, the control apparatus 7 controls the drive systems 105 and thereby controls the positions of the first substrate stage 51 and the second substrate stage 52.

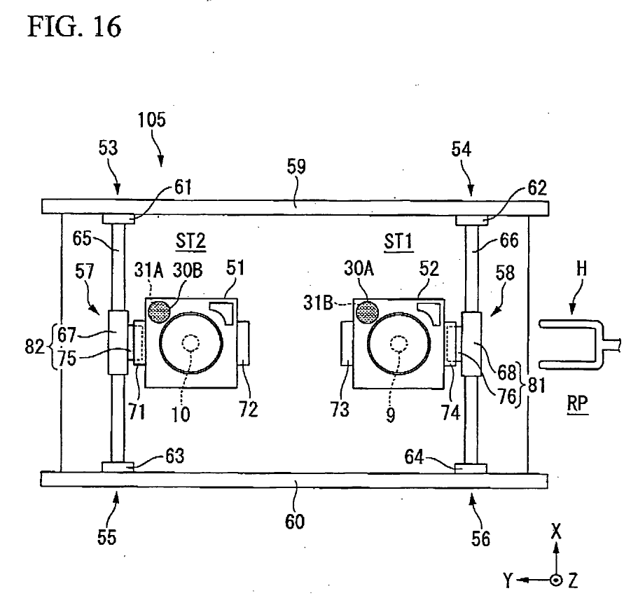

FIG. 16 is a plan view of the first substrate stage 51 and the second substrate stage 52. In FIG. 16, the drive system 105 that moves the first substrate stage 51 and the second substrate stage 52 comprises a plurality of linear motors 53, 54, 55, 56, 57, 58. The drive system 105 comprises two Y axis guide members 59, 60, each of which extends in the Y axial directions. Each of the Y axis guide members 59, 60 comprises a magnet unit that has a plurality of permanent magnets. One of the Y-axis guide members, i.e., the Y axis guide member 59, supports two slide members 61, 62 so that they are movable in the Y axial directions, and the other Y axis guide member, i.e., the Y axis guide member 60, supports two slide members 63, 64 so that they are movable in the Y axial directions. Each of the slide members 61, 62, 63, 64 comprises a coil unit, which has an armature coil. Namely, in the present embodiment, the slide members 61, 62, each of which has a coil unit, and the Y axis guide member 59, which has a magnet unit form the moving coil type Y axis linear motors 53, 54. Similarly, the slide members 63, 64, each of which has a coil unit and the Y axis guide member 60, which has a magnet unit, form the moving coil type Y as linear motors 55, 56.

In addition, the drive system 105 comprises two X axis guide members 65, 66, each of which extends in the X axial directions. Each of the X axis guide members 65, 66 comprises a coil unit, which has an armature coil. One of the X axis guide members, i.e., the X axis guide member 65, supports a sliding member 67 that is connected to the first substrate stage 51 so that it is movable in the X axial directions, and the other X axis guide member, i.e., the X axis guide member 66, supports a sliding member 68 that is connected to the second substrate stage 52 so that it is movable in the X axial directions. Each of the sliding members 67, 68 comprises a magnet unit, which has a plurality of permanent magnets. Namely, in the present embodiment, the sliding member 67 that has a magnet unit and the X axis guide member 65 that has a coil unit form the moving magnet type X axis liner motor 57, which drives the first substrate stage 51 in the X axial directions. Similarly, the sliding member 68 that has a magnet unit and the X axis guide member 66 that has a coil unit form the moving magnet type X axis linear motor 58, which drives the second substrate stage 52 in the X vial directions.

The slide members 61, 63 are fixed to one end and another end, respectively, of the X axis guide member 65, and the slide members 62, 64 are fixed to one end and another end, respectively, of the X axis guide member 66. Accordingly, the X axis guide member 65 is movable in the Y axial directions by the Y axis linear motors 53, 55, and the X axis guide member 66 is movable in the Y axial directions by the Y axis linear motors 54, 56.

Furthermore, it is possible to control the position of the first substrate stage 51 in the θZ directions by creating a slight difference in the to generated by each of the Y axis linear motors 53, 55, and to control the position of the second substrate stage 52 in the θZ directions by creating slight differences in the thrusts generated by each of the Y axis linear motors 54, 56.

In addition, although not shown, the drive system 105 comprises actuators, such as voice coil motors, that are capable of moving (fine moving) each of the stages 51, 52 with six degrees of freedom.

In addition, the first substrate stage 51 and the second substrate stage 52 are connected releasably to the slide members 67, 68, respectively, via joint members, as disclosed in, for example, Published Japanese Translation No. 2000-505958 of the PCT International Publication, Published Japanese Translation No. 2000-511704 of the PCT International Publication, Japanese Patent Application, Publication No. 2001-223159, and U.S. Pat. No. 6,262,796.

As shown in FIG. 15 and FIG. 16, the first substrate stage 51 comprises a first joint member 71, which is provided to its side surface on the +Y side, and a second joint member 72, which is provided to its side surface on the −Y side. Similarly, the second substrate stage 52 comprises a third joint member 73, which is provided to its side surface on the +Y side, and a fourth joint member 74, which is provided to its side surface on the −Y side.

In addition, the drive system 105 comprises a joint member 75, which is provided to the slide member 67, and a joint member 76, which is provided to the slide member 68. The joint member 75 is provided to a side surface of the slide member 67 on the −Y side so that it faces the measurement station ST1 side (the −Y side). The joint member 76 is provided to a side surge of the slide member 68 on the +Y side so that it faces the exposure station ST2 side (the +Y side).

The slide member 67 and the joint member 75 are fixed and the slide member 67 and the joint member 75 are capable of moving together. In addition, the slide member 68 and the joint member 76 are fixed and are capable off moving together. Accordingly, the linear motors 53, 55, 57 are capable of moving the slide member 67 and the joint member 75 together, and the linear motors 54, 56, 58 are capable of moving the slide member 68 and the joint member 76 together.

The first joint member 71 of the first substrate stage 51 and the third joint member 73 of the second substrate stage 52 are connected releasably and successively to the joint member 75, which is provided to the slide member 67. The second joint member 72 of the first substrate stage 51 and the fourth joint member 74 of the second substrate stage 52 are connected releasably and successively to the joint member 76, which is provided to the slide member 68.

Namely, the first substrate stage 51 and the second substrate stage 52 are connected releasably and successively to the joint member 75, which is provided to the slide member 67, via the first joint member 71 and the third joint member 73, and are also connected releasably and successively to the joint member 76, which is provided to the slide member 68, via the second joint member 72 and the fourth joint member 74.

In the explanation below, the combination of the joint member 76, to which the first substrate stage 51 and the second substrate stage 52 are connected releasably and successively, and the slide member 68, whereto that joint member 76 is fixed, is properly called a first connecting member 81. In addition, the combination of the joint member 75, to which the first substrate stage 51 and the second substrate stage 52 are connected releasably and successively, and the slide member 67, whereto that joint member 75 is fixed, is properly called a second connecting member 82.

In addition, the control apparatus 7 carries out, on the base member BP and at a prescribed time, the disconnection of the first connecting member 81 and the first substrate stage 51 (or the second substrate stage 52), the disconnection of the second connecting member 82 and the second substrate stage 52 (or the first substrate stage 51), the connection of the first connecting member 81 and the second substrate stage 52 (or the first substrate stage 51), and the connection of the second connecting member 82 and the first substrate stage 51 (or the second substrate stage 52). Namely, at a prescribed time, the control apparatus 7 performs the exchange operation (switching operation) wherein the first connecting member 81 and the second connecting member 82 are switched between the first substrate stage 51 and the second substrate stage 52.

Furthermore, the second connecting member 82 is connected alternately to the first joint member 71 of the first substrate stage 51 and the third joint member 73 of the second substrate stage 52, and the first connecting member 81 is connected alternately to the second joint member 72 of the first substrate stage 51 and the fourth joint member 74 of the second substrate stage 52. Namely, the second connecting member 82 is connected alternately to the first substrate stage 51 and the second substrate stage 52 via the first joint member 71 and the third joint member 73, and the first connecting member 81 is connected alternately to the first substrate stage 51 and the second substrate stage 52 via the second joint member 72 and the fourth joint member 74.

The linear motors 54, 56, 58 are capable of moving the first connecting member 81, and the linear motors 53, 55, 57 are capable of moving the second connecting member 82. The first connecting member 81 uses the drive of the linear motors 54, 56, 58 to move one of the substrate stages of the first substrate stage 51 and the second substrate stage 52 to which it is connected, and the second connecting member 82 uses the drive of the linear motor 53, 55, 57 to move the other substrate stage to which it is connected. In addition, the first connecting member 81 principally moves the measurement station ST1, and the second connecting member 82 principally moves the exposure station ST2.

In addition, as shown in FIG. 16, the transport system H, which exchanges the substrate P, is provided in the vicinity of the measurement station ST1. The control apparatus 7 is capable of using the transport system H to perform the substrate exchange operation, which includes the operation unloads the exposure processed substrate P from the first substrate stage 51 (or the second substrate stage 52) that has moved to the substrate exchange position (loading position) RP in the measurement station ST1, and the operation that loads the substrate P to be exposure processed onto the first substrate stage 51 (or the second substrate stage 52).

As shown in FIG. 16, in the present embodiment, the exposure apparatus EX comprises the first cap member 30A that can be held at the first position, which opposes the first optical element 9 of the alignment system 8, and the second cap member 30B that can be held at the second position, which opposes the second optical element 10 of the projection optical system PL.

In addition, in the present embodiment, the exposure apparatus E comprises a first cap holder 31A, which holds the first cap member 30A and the second cap member 30B detachably to the first substrate stage 51, and a second cap holder 31B, which holds the first cap member 30A and the second cap member 303 detachably to the second substrate stage 52. The first cap holder 31A is disposed on the first substrate stage 51 and the second cap holder 31B is disposed on the second substrate stage 52.

In the present embodiment, the first cap member 30A and the second cap member 30B have substantially the same size and shape, and the first cap holder 31A and the second cap holder 31B hive substantially equivalent configurations.

The first and second cap holders 31A, 31B have, for example, vacuum chuck mechanisms and chuck the first and second cap members 30A, 30B. Furthermore, if the first and second cap members 30A, 30B are formed from a magnetic body (metal), then the first and second cap holders 31A, 31B are configured to hold the first and second cap members 30A, 30 with magnetic force.

The front surface (the upper surface) of the first cap member 30A or the second cap member 30B that is held by the first cap holder 31A is substantially flush with an upper surface 51A of the first substrate stage 51. Similarly, the front surface (the upper surface) of the first cap member 30A or the second cap member 30B that is held by the second cap holder 31B is substantially flush with an upper surface 52F of the second substrate stage 52.

The control apparatus 7 is capable of moving the first cap member 30A to the first position, which opposes the first optical element 9, by moving one of the stages of the first and second substrate stages 51, 52 that holds the first cap member 30A. Similarly, the control apparatus 7 is capable of moving the second cap member 30B to the second position, which opposes the second optical element 10, by moving one of the stages of the first and second substrate stages 51, 52 that holds the second cap member 30B.

The first space SP1, which is capable of holding the first liquid LQ1, is formed between the first cap member 30A, which is disposed at the first position, and the first optical element 9. The second space SP2, which is capable of holding the second liquid LQ2, is formed between the second cap member 30B, which is disposed at the second position, and the second optical element 10.

Wile the control apparatus 7 performs the operation that acquires positional information about the substrate P through the first optical element 9 of the alignment system 8 and the first liquid LQ1 (specifically, while performing the operation of detecting, for example, an alignment mark on the substrate P through the first optical element 9), the first cap member 30A is held by the cap holder (31A or 31B) of the substrate stage (51 or 52) that holds that substrate P.

In addition, while the control apparatus 7 performs an immersion exposure of the substrate P through the second optical element 10 of the projection optical system PL and the second liquid LQ2, the second cap member 30B is held by the cap holder (31A or 31B) of the substrate stage (51 or 52) that holds that substrate P.

In addition, in the present embodiment, the expose apparatus EX comprises a first cap holding mechanism 84 that holds the first cap member 30A at the first position, which opposes the first optical element 9, and a second cap holding mechanism 90 that holds the second cap member 30B at the second position, which opposes the second optical element 10.

The first cap holding mechanism 84 has a configuration that is similar to that of the cap holding mechanism 40, which was explained in the first embodiment discussed above. The explanation thereof is omitted.

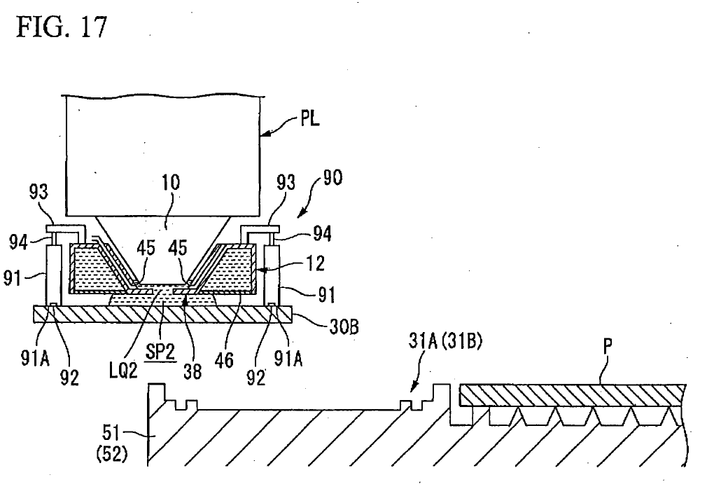

FIG. 17 is a view that shows the second cap holding mechanism 90. As shown in FIG. 17, the second cap holding mechanism 90 is capable of holding the second cap member 30B so that the second space SP2, which is capable of holding the second liquid LQ2, is formed between the second optical element 10 and the second cap member 30B.

At least part of the second cap holding mechanism 90 is connected to the second nozzle member 12 and detachably holds the second cap member 30B. The second cap holding mechanism 90 chucks the second cap member 30B.

In the present embodiment, the second cap holding mechanism 90 has a configuration that is substantially equivalent to that of the second cap holding mechanism 84 (90). Namely, the second cap holding mechanism 90 comprises: holding members 91, each of which is capable of opposing an upper surface of the second cap member 30B and has a lower surface 91A that is capable of holding the upper surface of the second cap member 30B; and suction ports 92, which are formed in the lower surfaces 91A of the holding members 91 and chuck the second cap member 30B. The holding members 91 are capable of moving with respect to the second nozzle member 12, and a plurality (for example, three) thereof is disposed on the outer side of the second nozzle member 12 (the recovery port 46). Support members 93, which correspond to the holding members 91, are provided on the upper sure of the second nozzle ember 12, and drive mechanisms 44, which move the holding members 91 in the Z axial directions with respect to the support members 93, are provided between the support members 93 and the holding members 91. The control apparatus 7 can move the holding members 91 in the vertical directions on the outer side of the second nozzle member 12 by driving the drive mechanisms 94. The cap holding mechanism 90 holds prescribed areas of the upper surface of the second cap member 30B with the lower surfaces 91A of the holding members 91.

If the second cap holding mechanism 90 is used to hold the second cap member 30B, then, as shown in FIG. 17, the control apparatus 7 uses the drive mechanisms 94 to lower the lower surfaces 91A of the holding members 91 so that they are lower than the lower surface 38 of the second nozzle member 12, and uses the suction ports 92, which are provided in the lower surfaces 91A of the holding members 91, to chuck the upper surface of the second cap member 30B.

During the exposure of the substrate P through the projection optical system PL and the second liquid LQ2, the control apparatus 7 prevents contact between the holding members 91 and the substrate P, the first ad second substrate stages 51, 52, and the like, by using the drive mechanisms 94 to raise the holding members 91 so that the lower surfaces 91A of the holding members 91 are positioned above (on the +Z axis side) the lower surface 38 of the second nozzle member 12.

Furthermore, the holding members 91 are connected to the second nozzle member 12 via the drive mechanisms 94 and the support members 93, but they may be connected, for example, to the lens barrel PK of the projection optical system PL or a body (column) of the exposure apparatus EX that supports the lens barrel PK.

In the present embodiment, when the first cap holding mechanism 84 holds the first cap member 30A, the operation of supplying liquid via the supply port 33 of the first nozzle member 11 and the operation of recovering liquid via the recovery port 34 of the first nozzle member 11 are performed in parallel with the cool apparatus 7. Similarly, when the second cap holding mechanism 90 holds the second cap member 30B, the control apparatus 7 performs the operation of supplying liquid via the supply port 45 of the second nozzle member 12 and the operation of recovering liquid via the recovery port 46 of the second nozzle member 12 in parallel. In the embodiment, the cap holding mechanism 90 holds the tap member (30A, 30B) so that the lower surface 91A of the holding member 91 and the upper surface of the cap member (30A, 30B) make contact with each other, however, it may hold the cap member so that they do not contact with each other.

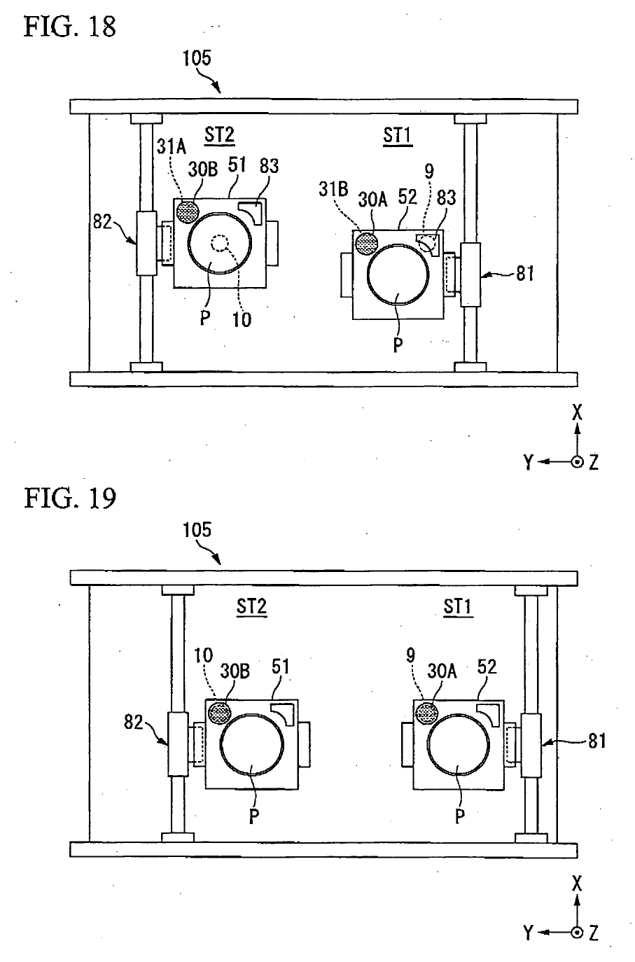

The following explains one example of the operation of the exposure apparatus that has the configuration discussed above, referencing FIG. 18 through FIG. 23.

In the present embodiment, while the process of exposing the substrate P that is held on one of the substrate stages of the first substrate stage 51 and the second substrate stage 52 is performed in the exposure station ST2, the other substrate stage is used to perform a prescribed measurement process in the measurement station ST1.

Specifically, while controlling the movement of one of the substrate stages of the first substrate stage 51 and the second substrate stage 52 that is in the exposure station ST2, the control apparatus 7 exposes the substrate P, which is held by that substrate stage, through the projection optical system PL and the second liquid LQ2. Moreover, the control apparatus 7 uses the alignment system 8 to acquire positional information about the unexposed substrate P that is held by the other substrate stage that is in the measurement station ST1.

The control apparatus 7 exchanges (loads and/or unloads) the substrate P and starts the prescribed measurement process in the measurement station ST1. For example, the control apparatus 7 disposes the second substrate stage 52 at the substrate exchange position RP in the measurement station ST1 and uses the transport system H to load the substrate P to be exposure processed to the second substrate stage 52. The second substrate stage 52 holds the substrate P. Furthermore, the control apparatus 7 starts the process of measuring the substrate P that is held by the second substrate stage 52 in the measurement station ST1. Moreover, the first substrate stage 51, which holds the substrate P for which the measurement process in the measurement station ST1 has been completed, is disposed in the exposure station ST2, and the exposure of the substrate P, which is held by the first substrate stage 51, starts.

As shown in FIG. 18, the control apparatus 7 uses the drive system 105 to move the first substrate stage 51 by moving the second connecting member 82, which is connected to the first substrate stage 51, and performs the exposure process on the substrate P that is held by the first substrate stage 51 in the exposure station ST2. In addition, the control apparatus 7 uses the drive system 105 to move the second substrate stage 52 by moving the first connecting member 81, which is connected to the second substrate stage 52, and then performs the measurement process on the substrate P that is held by the second substrate stage 52 in the measurement station ST1 in parallel with at least part of the process of exposing the substrate F is held by the first substrate stage 51.

The control apparatus 7 performs an immersion exposure of the substrate P that is held by the first substrate stage 51 in the exposure station ST2. In a state wherein the second immersion space is formed by causing the substrate P and the second optical element 10 to oppose one another, the control apparatus 7 exposes the substrate P through the second optical element 10 and the second liquid LQ2 of the second immersion space.

The first cap holder 31A of the first substrate stage 51 holds the second cap member 30B while the immersion exposure of the substrate P is performed through the second optical element 10 of the projection optical system PL and the second liquid LQ2.

In the measurement station ST1, the alignment system 8 detects an alignment mark on the substrate P that is held by the second substrate stage 52, while the immersion exposure, which uses the first substrate stage 51, is performed in the exposure station ST2. In addition, in the present embodiment, a measurement area 83, wherein a fiducial mark is formed, is provided on part of the second substrate stage 52, and the alignment system 8 also detects this fiducial mark. As shown in FIG. 18, in a state wherein the first immersion space is formed by moving the second substrate stage 52 that holds the substrate P to the first position, which opposes the first optical element 9 of the alignment system 8, the control apparatus 7 uses the alignment system 8 to detect the fiducial mark that is formed on part of the second substrate stage 52 and an alignment mark on the substrate P in the measurement station ST1 while continuing to measure the positional information of the second substrate stage 52 with the measurement system 106. The alignment system 8 detects an alignment mark on the substrate P and the fiducial mark on the second substrate stage 52 through the first liquid LQ1 of the first immersion space. Furthermore, the control apparatus 7 uses arithmetic processing to derive positional information for each shot region of the plurality of shot regions on the substrate P with respect to the fiducial mark.

The second cap holder 31B of the second substrate stage 52 holds the first cap member 30A wile the operation is performed that uses the alignment system 8 to acquire positional information about the substrate P.

In addition, measurement at the measurement station ST1 includes the detection operation that uses the focus leveling detection system, which is disposed in the measurement station ST1. For example, with the detection operation that uses the focus leveling detection system, the control apparatus 7 uses the focus leveling detection system to detect a prescribed reference surface and the surface positional information about the front surface of the substrate P in the measurement station ST1 while measuring the positional information of the second substrate stage 52 in the Z axial directions with the Z interferometer that was discussed above. Furthermore, the control apparatus 7 uses the reference surface as a reference to derive an approximation plane (an approximation surface) for each shot region on the front surface of the subsume P. Furthermore, in the present embodiment, the measurement of the reference surface and the surface positional information about the front surface of the substrate P is performed through the first liquid LQ1 by the focus leveling detection system, but it may be performed without passing through the first liquid LQ1.

After the immersion exposure of the substrate P that held by the first substrate stage 51 and the process of measuring the substrate P that is held by the second substrate stage 52 are complete, the control apparatus 7 controls the drive system 105 so as to move the second substrate stage 52 so that the first cap member 30A held by the second cap holder 31B is disposed at the first position, which opposes the first optical element 9 of the measurement station ST1, as shown in FIG. 19. Thereby, the first space SP1, which is filled with the first liquid LQ1, is formed between the first optical element 9 and the first cap member 30A.

The control apparatus 7 uses the first cap holding mechanism 84 to hold the first cap member 30A, and releases the hold of the first cap member 30A by the second cap holder 31B. Thereby, the first cap member 30A is held by the first cap holding mechanism 84 so that it is spaced apart from the second cap holder 31B while the first space SP1, which is filled with the first liquid LQ1, is maintained.

In addition, as shown in FIG. 19, the control apparatus 7 controls the drive system 105 so as to move the first substrate stage 51 so that the second cap member 30B, which is held by the first cap holder 31A, is disposed at the second position, which opposes the second optical element 10 of the exposure station ST2. Thereby, the second space SP2, which is filled with the second liquid LQ2, is formed between the second optical element 10 and the second cap member 30B.

The control apparatus 7 uses the second cap holding mechanism 90 to hold the second cap member 30B, and releases the hold of the second cap member 30B by the first cap holder 31A. Thereby, the second cap member 30B is held by the second cap holding mechanism 9050 that it is spaced apart from the first cap holder 31A while the second space SP2, which is filled with the second liquid LQ2, is maintained.

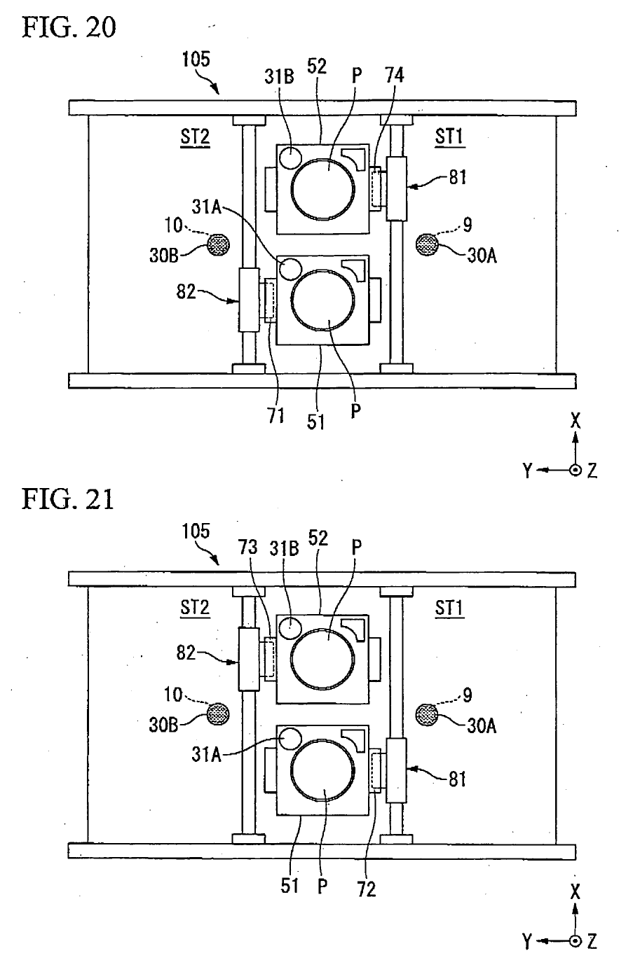

After the first cap holding mechanism 84 holds the first cap member 30A at the first position and the second cap holding mechanism 90 holds the second cap member 30B at the second position, the control apparatus 7 controls the drive system 105 so as to move the first substrate stage 51 toward the measurement station ST1 and the second substrate stage 52 toward the exposure station ST2. As shown in FIG. 20, in the present embodiment, the first substrate stage 51 and the second substrate stage 52 are disposed at positions that are lined up in the X axial directions while they are being moved. In the present embodiment, as shown in FIG. 20, the second substrate stage 52 is disposed on the +X side of the first substrate stage 51.

Next, as shown in FIG. 21, the control apparatus 7 releases the connection between: the first connecting member 81 and the fourth joint member 74 of the second substrate stage 52, thereby releasing the second substrate stage 52 from the first connecting member 81; and the second connecting member 82 and the first joint member 71 of the first substrate stage 51, thereby releasing the first substrate stage 51 from the second connecting member 82. Subsequently, the control apparatus 7 moves the first connecting member 81 in the −X direction and connects it to the second joint member 72 of the first substrate stage 51, and moves the second connecting member 82 in the +X direction and connects it to the third joint member 73 of the second substrate stage 52.

Thus, in the exchange operation, the first connecting member 81, which was connected to the second substrate stage 52, is connected to the first substrate stage 51, and the second connecting member 82, which was connected to the first substrate stage 51, is connected to the second substrate stage 52.

Furthermore, the control apparatus 7 controls the drive system 105 so as to move the second substrate stage 52, which is connected to the second connecting member 82, to the exposure station ST2, and the first substrate stage 51, which is connected to the first connecting member 81, to the measurement station ST1.

The exposure processed substrate P held by the first substrate stage 51 that moved to the measurement station ST1 is unloaded by the transport system f at the substrate exchange position RP and a new substrate P that is to be exposed is loaded onto the first subsume stage 51.

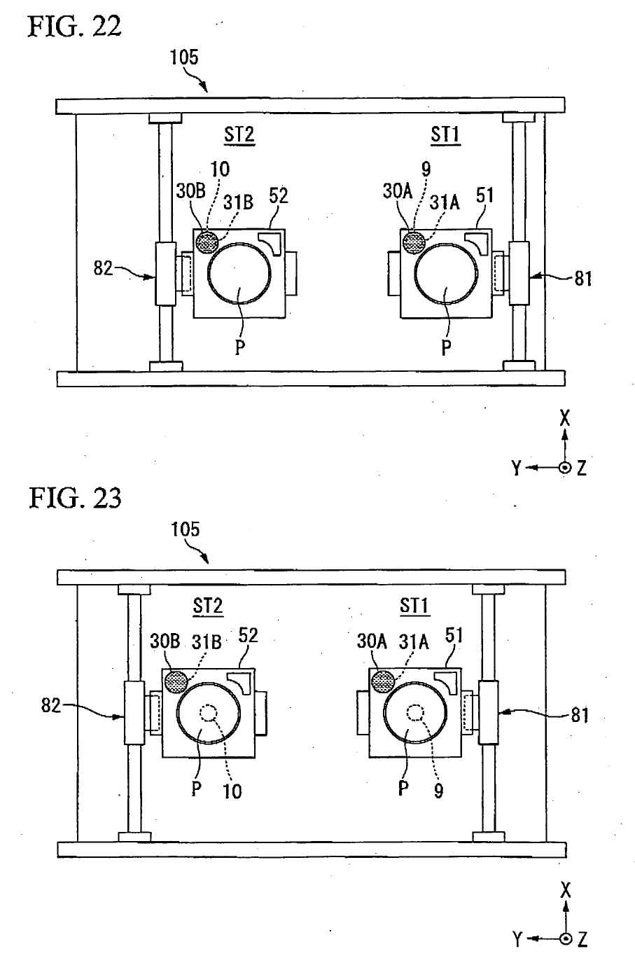

In the measurement son ST1 as shown in FIG. 22, after the substrate P is loaded onto the first substrate sage 51, the control apparatus 7 moves the first substrate stage 51 so that the first cap holder 31A of the first substrate stage 51 and the first cap member 30A held by the first cap holding mechanism 84 are opposed.

Furthermore, the control apparatus 7 controls the first cap holding mechanism 84, which is held by the first cap member 30A, so as to mount the first cap member 30A to the first cap holder 31A the measurement station ST1 while maintaining the first space SP1 (the first immersion space), which is filled with the first liquid LQ1. Furthermore, the control apparatus 7 releases the hold of the first cap member 30A by the first cap holding mechanism 84 and uses the first cap holder 31A to chuck the first cap member 30A. Thereby, the first cap member 30A is held by the first cap holder 31A so that it is spaced apart from the first cap holding mechanism 84.

In addition, in the exposure station ST2 as shown in FIG. 22, the control apparatus 7 moves the second substrate stage 52 so that the second cap holder 31B of the second substrate sage 52 and the second cap member 30B held by the second cap holding mechanism 90 are opposed.

Furthermore, the control apparatus 7 controls the second cap holding mechanism 90, which is held by the second cap member 30B, so as to mount the second cap member 30B to the second cap holder 31B in the exposure station ST2 while maintaining the second space SP2 (the second immersion space), which is filled with the second liquid LQ2. Furthermore, the control apparatus 7 releases the hold of the second cap member 30B by the second cap holding mechanism 90 and chucks the second cap member 30B with the second cap holder 31B. Thereby, the second cap member 303 is held by the second cap holder 31B so that it is spaced apart from the second cap holding mechanism 90.

Furthermore, the operation at acquires positional information about the substrate P that is held by the first sure stage 51 is performed in the measurement station ST1. As shown in FIG. 23, the control apparatus 7 uses the alignment system 8 to detect an alignment mark on the substrate P and a fiducial mark that is provided on the first substrate stage 51 in a state wherein the first immersion space is formed by causing the first substrate step 51, which holds the substrate P, and the first optical element 9 to oppose one another.

In addition, an immersion exposure is performed for the substrate P that is held by the second substrate stage 52 in the exposure station ST2. The control apparatus 7 exposes the substrate P in a state wherein the second immersion space is formed by causing the second substrate stage 52, which holds the substrate P, and the second optical element 10 to oppose one another.

When the substrate P is to be exposed, the control apparatus 7 adjusts the position of the substrate P, which is held by the second substrate stage 52, in the exposure station ST2, while using the results of the measurements ma at the measurement station ST1.

Subsequently, the processes that were explained referencing FIG. 18 through FIG. 23 are performed repetitively so that the measurement process and the exposure process are performed for a plurality of substrates P while maintaining the first space SP1, which is filled with the first liquid LQ1, and the second space SP2, which is filled with the second liquid LQ2.

As explained above, in the present embodiment, it is possible to dispose at least one of the first substrate stage 51, the second substrate stage 52, and the first cap member 30A at the first position, which opposes the first optical element 9, continuously. Accordingly, it is possible to continue forming the first space SP1, which is capable of holding the first liquid LQ1, between the first optical element 9 and at least one of the first substrate 51, the substrata P is held by the first substrate stage 51, the second substrate stage 52, the substrate P that is held by the second substrate stage 52, and the first cap member 30A. Accordingly there is no need to perform the operation that recovers all of the first liquid LQ1 or the operation that stops the supply of the first liquid LQ1, and therefore it is possible to prevent, for example, a decrease in the throughput of the exposure apparatus EX and deterioration of the first optical element 9. Accordingly, it is possible to use the alignment system 8 to acquire positional information about the substrate P accurately and to expose the substrate P satisfactorily and efficiently.

In addition, in the present embodiment, it is possible to dispose at least one of the first substrate stage 51, the second substrate stage 52, and the second cap member 30B at the second position, which opposes the second optical element 10, continuously. Accordingly, it is possible to continue forming the second space SP2, which is capable of holding the second liquid LQ2, between the second optical element 10 and at least one of the first substrate stage 51, the substrate P that is held by the first substrate stage 51, the second substrate stage 52, the substrate P that is held by the second substrate stage 52, and the second cap member 30B. Accordingly, there is no need to perform the operation that recovers all of the second liquid LQ2 or the operation that stops the supply of the second liquid LQ2, and therefore it is possible to prevent for example, a decrease in the throughput of the exposure apparatus EX and deterioration of the second optical element 10. Accordingly, it is possible to use the projection optical system PL to expose the substrate P satisfactorily and efficiently.

Furthermore, immediately after the measurement process, which uses the alignment system 8, is complete, the first cap holding mechanism 84 may be used to hold the first cap member 30A at the first position. Namely, there is no need to perform the operation of holding the first cap member 30A by the first cap holding mechanism 84 and the operation of holding the second cap member 30B by the second cap holding mechanism 90 simultaneously; for example, depending on the processing status of the measurement station ST1 and of the exposure station ST2, while a process is performed at one of the stations, the cap holding mechanism of the other station may perform the operation of holding the cap member.

Furthermore, in the present embodiment as well, the measuring instrument that is capable of performing measurements with respect to the exposure may be mounted to the cap member (the 30A and/or the 30B). In particular, when the second cap member 30B is held by the second cap holding mechanism 90 and positioned at the second position, it is possible to use the measuring instrument of the second cap member 30B to perform measurements using the exposure light EL in a manner that is similar to that of the embodiment discussed above. In addition the second cap member 30B may be provided with a transmitting apparatus that wirelessly transmits the measuring instrument's measurement results, which may be wirelessly transmitted to the control apparatus 7 (or a receiving apparatus that is connected to the control apparatus 7).

Furthermore, also in the embodiment when one of the second cap holding mechanism 90 and the cap holder (31A, 31B) holds the cap member 30A, which is released from the other one, only the holding member 91 moves along the Z directions, however, only the substrate stage (51, 52) may move along the Z directions, or both the holding member 91 and the substrate stage (51, 52) may move along the Z directions.

Furthermore, in the above description, one the first optical element 9 (the alignment system 8) is provided, however, a plurality of first optical elements 9 (alignment systems 8) may be provided so as to detect a plurality of mars substantially at the same time.

### Fourth Embodiment

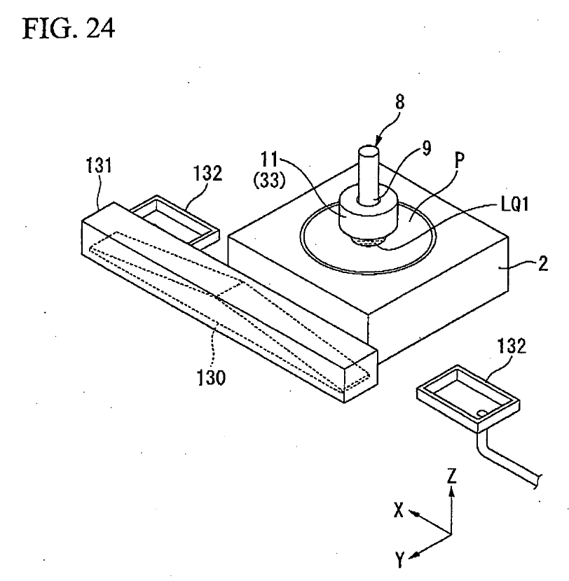

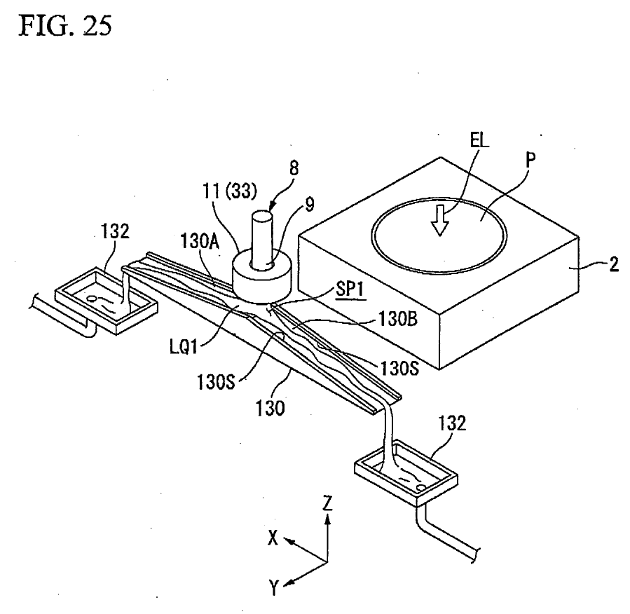

The follow explains a fourth embodiment FIG. 24 and FIG. 25 are oblique views that schematically show part of the exposure apparatus EX according to the fourth embodiment. Furthermore, although not shown in detail, the exposure apparatus EX of the present embodiment comprises the substrate stage 2 and the measurement stage 3 as explained in the first and second embodiments discussed above, and the measurement stage 3 is omitted from FIG. 24 and FIG. 25. In the explanation below, constituent parts that are identical or equivalent to those in the embodiments discussed above are assigned identical symbols, and the explanations thereof are therefore abbreviated or omitted.

As shown in FIG. 24 and FIG. 25 and similar to the embodiments discussed above, the exposure apparatus EX of the present embodiment comprises the first optical element 9 of the alignment system 8 and the first nozzle member 11, which is capable of forming the first immersion spare. Furthermore, the exposure apparatus EX of the present embodiment moves a movable member that is different from the substrate stage 2 and the measurement sage 3 to the first position, which opposes the fast optical element 9 of the alignment system 8; thereby, in the present embodiment wherein the first space SP1, which is capable of holding the first liquid LQ1, is maintained even when the substrate stage 2 and the measurement stage 3 are spaced apart from the first position. In the embodiment, disposing a movable member 130 at the first position makes it possible to form the first space SP1, which is capable of holding the first liquid LQ1, between the first optical element 9 and the movable member 130. The first nozzle member 11 comprises the supply port 33 that supplies the first liquid LQ1.

In addition, in the present embodiment, the exposure apparatus EX comprises recovery members 132, which recover the first liquid LQ1 that was brought to the movable member 130 via the supply port 33. The recovery members 132 are disposed at prescribed positions that are below the substrate stage 2. In the present embodiment, the recovery members 132 are disposed at prescribed positions on the +X side and the −X side, respectively, of the substrate stage 2.

As shown in FIG. 24, the exposure apparatus EX comprises a housing member 131, which is capable of housing the movable member 130. The housing member 131 is disposed at a position at which it does not obstruct, for example, the process of exposing the substrate P and the prescribed measurement process that uses the first optical element 9. In the present embodiment, the housing member 131 is disposed on the +Y side of the first optical element 9 at a position that does not interfere with the substrate stage 2 (and the measurement stage 3). In addition, although not shown, the exposure apparatus EX comprises a drive mechanism that is capable of holding and moving the movable member 130. The drive mechanism is capable of moving the movable member 130 to the first position and is capable of moving to an inner side of (is capable of being housed in) the housing member 131.

As shown in FIG. 24, the subsume stage 2 (or the measurement stage 3) is disposed at the fit position, which opposes the first optical element 9, and the control apparatus 7 controls the drive mechanism so as to house the movable member 130 in the housing member 131 at least during the performance of the operation that acquires positional information about the substrate P through the first optical element 9 (the operation that detects an alignment murk on the substrate P and the operation that detects the fiducial mark on the measurement stage 3). Thereby, without being obstructed by the movable member 130, the exposure apparatus EX can perform, for example, the measurement process that uses the first optical element 9 and wherein the substrate stage 2 (or the measurement stage 3) is disposed at the first position.

In the present embodiment as shown in FIG. 25, during, for example, the exposure of the substrate P that is held by the substrate stage 2, the control apparatus 7 controls the drive mechanism so as to move the movable member 130 to the first position. The first space SP1, which is capable of holding the first liquid LQ1, is maintained between the movable member 130 and the first optical element 9. Furthermore, it is also possible to move the movable member 130 to the first position as appropriate not only during the exposure of the substrate P but also when neither the substrate stage 2 nor the measurement stage 3 opposes the first position, which opposes the first optical element 9, such as during the operation of exchanging the substrate that is on the substrate stage 2.

In the present embodiment, the supply port 33 of the first nozzle member 11 continues the liquid supply operation even in the state wherein the movable member 130 is disposed at the first position, which opposes the first optical element 9.

As shown in FIG. 25, the movable member 130 comprises two inclined surfaces 130A, 130B, which are inclined so that they decline as they go toward the +X direction and the −X direction, respectively. The first liquid LQ1 that is brought to the movable member 130 via the supply port 33 is conveyed along the two inclined surfaces 130A, 130B of the movable member 130 and then recovered in the recovery members 132, which are disposed on opposite sides of the substrate stage 2. In addition, two side plates 130S are disposed on the +Y side and the −Y side, respectively, of the inclined surfaces 130A, 130B and prevent the first liquid LQ1 that flows along the inclined surfaces 130A, 130B from leaking.

Furthermore, when the operation that acquires positional information about the substrate P through the first optical element 9 is performed, the control apparatus 7 retracts the movable member 130 from the first position and houses it in the housing member 131.

Furthermore, because the movable member 130 discussed above is provided with, for example, passageways (inclined surface) along which the first liquid LQ1 flows, the first nozzle member 11 does not need to be provided with a recovery port.

In addition, the shape and structure of the movable member 130 is not limited to that shown in FIG. 24 and FIG. 25; for example, the upper surface of the movable member 130 may be formed flatly. In this case, a recovery part that recovers the first liquid LQ1 may be provided to the movable member 130; alternatively, the recovery port of the first nozzle member 11 may be used without providing a recovery part to the movable member 130.

In addition, when an object (at least one of the substrate stage 2, the substrate P, and the measurement stage 3) opposes the first optical element 9, that object may be moved after the movable member 130 is inserted between the object and the first optical element 9 so that the first space SP1 is formed between the first optical element 9 and the movable member 130.

In addition, similar to the method described in FIG. 7 and the like, the object (the substrate stage 2 or the measurement stage 3), which opposes the first optical element 9, and the movable member 130 may be brought into close proximity or contact, a flat part may be formed that is continuous with the upper surface of that object and the upper surface of the movable member 130, the first optical element 9 and at least one of the object and the movable member 130 may be caused to oppose one another, and thereby the first space SP1, which is capable of holding the first liquid LQ1, may be main ed.

Furthermore, the present embodiment explained an exemplary case wherein the exposure apparatus EX is an exposure apparatus that comprises the substrate stage 2 and the measurement stage 3; however, for example, even if the exposure apparatus EX is a multistage type (a twin stage type) exposure apparatus as explained in the third embodiment discussed above, it is possible to dispose, for example, the movable member 130 according to the present embodiment. In this case, the movable member 130 is provided in the measurement station ST1 so that it is capable of moving to the first position, which opposes the first optical element 9. In addition, the movable member may be provided in the exposure station ST2 so that it is capable of being disposed at the second position, which opposes the second optical element 10.

Furthermore, in each of the embodiments discussed above, the optical path space on the light emerging side (the image plane side) of the second optical element 10 of the projection optical system PL is filled with liquid (the second liquid), but it is also possible to use a projection optical system wherein the optical path space on the light impinging side (the object plane side) of the second optical element 10 is also filled with liquid, as disclosed in PCT International Publication No. WO2004/019128.

Furthermore, although the first and second liquids LQ1, LQ2 in the present embodiment are water, they may be liquids other than water, for example, if the light source of the exposure light EL is an F₂ laser, then the F₂ laser light will not transmit through water and therefore it would be acceptable to use a fluorine based fluid, such as perfluorinated polyether (PFPE) or fluorine based oil, that is capable of transmitting F₂ laser light as the first and second liquid LQ1, LQ2. In addition, it is also possible to use a liquid (e.g., cedar oil) that is transparent to the exposure light EL, has the highest possible refractive index, and is stable with respect to the projection optical system PL and the photoresist coated on the surface of the substrate P as the first and second liquids LQ1, LQ2.

In addition a liquid that has a refractive index of approximately 1.6 to 1.8 may be used as the first and second liquids LQ1, LQ2. The optical element (the terminus optical element FL and the like) of the projection optical system PL that contacts the first and second liquid LQ1, LQ2 may for example be formed from quartz (silica), or from fluorite, barium fluoride, strontium fluoride, lithium fluoride, sodium fluoride, or single-crystal materials of other fluoride compounds. Furthermore, the terminus optical element may be formed from materials with a refractive index higher than that of quartz or fluorite (for example 1.6 or higher). As materials with a refractive index of 1.6 or higher, for example, sapphire, germanium dioxide or similar disclosed in PCT International Publication No. WO 2005/059617, or potassium chloride (with a refractive index of approximately 1.75) disclosed in PCT International Publication No. WO 2005/059618, or similar can be used. Furthermore, a thin film having liquid affinity properties and/or a dissolution-preventing function may be formed on a portion of (including at least the contact faces with the liquid) or the entirety of the terminus optical element. Quartz has high affinity to liquid and thus a dissolution preventive film is not necessary therefor. However, as for fluorite, it is preferable that at least a dissolution preventive film be formed thereon. It is also possible to use various fluids, e.g., a supercritical fluid, as the first and second liquids LQ1, LQ2. As a liquid with refractive index higher than pure water (for example 1.5 or higher), for example isopropanol with a refractive index of approximately 1.5, glycerol (glycerin) with a refractive index of approximately 1.61, and other prescribed liquids having C—H bonds or O—H bonds, as well as hexane, heptane, decan, and other prescribed liquids (organic solvents), as well as decalin (decahydronapthalene) with a refractive index of approximately 1.60, may be used. Further, as the liquid two or more arbitrary liquids among these liquids may be mixed together and used, or one or more of these liquids may be added to (mixed with) pure water and used. Further, as the liquid, pure water to which H⁺, Cs⁺, K⁺, Cl⁻, SO₄²⁻; PO₄²⁻, or other bases or acids are added (mixed) may be used, or pure water to which an Al oxide or other fine particles have been added (mixed) may be used. Also, as the liquid, it is preferable that a liquid be used which has a low optical absorption coefficient, a small temperature dependence, and which is stable with respect to photosensitive materials (or topcoat films, or anti-reflection films, or similar) applied to the surfaces of the projection optical system and/or substrate. Id addition, a topcoat film or similar can be provided on the substrate to protect photosensitive materials or substrates from the liquid.

In addition, in the embodiments discussed above, the first liquid LQ1 and the second liquid LQ2 may be the same type of liquid, or they may be different types.

Furthermore, in each of the abovementioned embodiments, positional information about each stage is measured using the interferometer system, but the present invention is not limited thereto and, for example, an encoder system may be used that detects a scale (diffraction grating) that is provided to each stage. In this case, the system is configured as a hybrid system that is provided with both an interferometer system and an encoder system, and it is preferable to use the measurement results of the interferometer system to calibrate the measurement results of the encoder system. In addition, the position of the stages may be controlled by switching between the interferometer system and the encoder system, or by using both.

Furthermore, the substrates P in each of the abovementioned embodiments are not limited to semiconductor wafers for fabricating semiconductor devices and are also applicable to, for example, glass substrates for display devices, ceramic wafers for thin film magnetic heads, masks or the original plates of reticles (synthetic quartz or silicon wafers), film members, and similar used by an exposure apparatus. Moreover, substrates are not limited to round shapes, but may be rectangular or other shapes.

The exposure apparatus EX can also be adapted to a step-and-scan type scanning exposure apparatus (a scanning stepper) that scans and exposes the pattern of the mask M by synchronously moving the mask M and the substrate P, as well as to a step-and-repeat type projection exposure apparatus (a stepper) that performs full field exposure of the pattern of the mask M with the mask M and the substrate P in a stationary state, and sequentially steps the substrate P.

Furthermore, when performing an exposure with a step-and-repeat system, the projection optical system PL is used to transfer a reduced image of a first pattern onto the substrate P in a state wherein the first pattern and the substrate P are substantially stationary, after which the projection optical system PL may be used to perform a full-field exposure of the substrate P wherein a reduced image of a second pattern partially superposes the transferred first pattern (as in a stitching type full-field exposure apparatus). In addition, the stitching type exposure apparatus can also be adapted to a step-and-stitch type exposure apparatus that transfers at least two patterns onto the substrate P so that they partially overlap, and sequentially steps the substrate P.

Each of the abovementioned embodiments was explained by taking as an example an exposure apparatus is provided with the projection optical system PL, but the present invention can be adapted to an exposure apparatus and an exposing method that does not use the projection optical system PL. Even if the projection optical system PL is not used, the exposure light EL is radiated onto the substrate P through optical members, such as lenses, and immersion space is formed in a prescribed space between the substrate P and such optical members.

The type of exposure apparatus EX is not limited to a semiconductor device fabrication exposure apparatus that exposes the substrate P with the pattern of a semiconductor device, but can also be widely adapted to an exposure apparatus that is used for fabricating, for example, either liquid crystal devices or displays, and an exposure apparatus that is used for fabricating thin film magnetic heads, imaging devices (CCDs), micromachines, MEMS, DNA chips, or reticles and masks.

Furthermore, in the above mentioned embodiments, a light transmitting type mask is used wherein a prescribed shielding pattern (or a phase pattern or a pattern is formed on a light transiting substrate; however, instead of such a mask, it is also possible to use an electronic mask wherein a transmittance patter a reflected pattern, or a light emitting pattern is formed based on electronic data of the pattern to be exposed as disclosed in, for example, U.S. Pat. No. 6,778,257; here, electronic masks, which are also called variable forming masks, include, for example, a digital micromirror device (DMD), which is one type of a non light emitting image display device (also called a Spatial Light Modulator (SLM)). The exposure apparatus using a DMD is disclosed for example in U.S. Pat. No. 6,778,257.

In addition, by forming interference fringes on the substrate P, as disclosed in, for example, PCT International Publication No. WO2001/035168, the present invention can also be adapted to an exposure apparatus (a lithographic system) that exposes the substrate P with a line-and-space pattern.

In addition, the present invention can also be adapted to, for example, an exposure apparatus that combines the patters of two masks on a substrate through a projection optical system, and double exposes, substantially simultaneously, a single shot region on the substrate by a single scanning exposure, as disclosed in, for example, Published Japanese Translation No. 2004-519850 of the PCT International Publication (corresponding U.S. Pat. No. 6,611,316). In addition the present invention can also be adapted to, for example, a proximity type exposure apparatus and a mirror projection aligner.

As far as is permitted, the disclosures in all of the Publications and U.S. patents related to exposure apparatuses and the like cited in the above respective embodiments and modified examples, are incorporated herein by reference.

As described above, the exposure apparatus EX of the embodiments is manufactured by assembling various subsystems, including each constituent element, so that prescribed mechanical, electrical, and optical accuracies are maintained. To ensue these various accuracies, adjustments are performed before and after this assembly, including an adjustment to achieve optical accuracy for the various optical systems, an adjust to achieve mechanical accuracy for the various mechanical systems, and an adjustment to achieve electrical accuracy for the various electrical system. The process of assembling the exposure apparatus EX from the various subsystems includes, for example, the mechanical interconnection of the various subsystems, the wiring and connection of electrical circuits, and the piping and connection of the atmospheric pressure circuit. Naturally, before the process of assembling the exposure apparatus EX from these various subsystems, there are also the processes of assembling each individual subsystem. When the process of assembling the exposure apparatus EX from the various subsystems is complete, a comprehensive adjustment is performed to ensure the various accuracies of the exposure apparatus EX as a whole. Furthermore, it is preferable to manufacture the exposure apparatus EX in a clean room wherein, for example, the temperature and the cleanliness level are controlled.

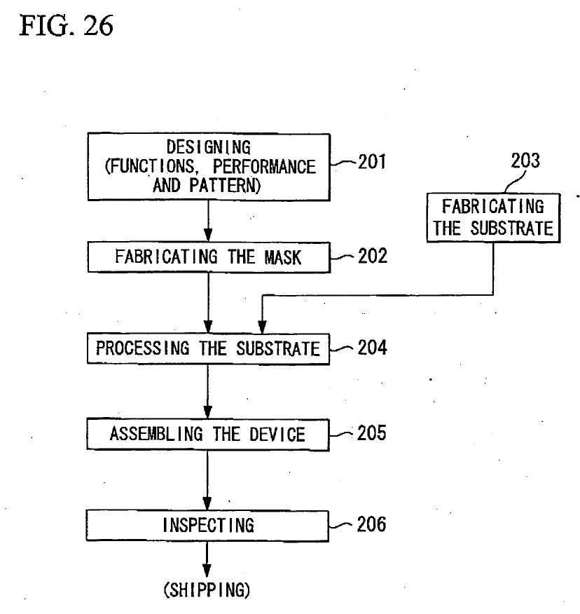

As shown in FIG. 26, a micro-device, such as a semiconductor device, is manufactured by: a step 201 that designs the functions and performance of the micro-device; a step 202 that fabricates a mask (a reticle) based on this design step; a step 203 that fabricates a substrate, which is the base material of the device; a substrate processing step 204 that includes substrate processes, e.g., a process wherein the substrate is irradiated with exposure light and exposed in accordance with the embodiments discussed above and a process that develops the exposed substrate; a device assembling step 205 (which includes fabrication processes such as dicing, bonding and packaging); an inspecting step 206; and the like.

1. An exposure apparatus that exposes a substrate with an exposure beam, comprising:
a first optical member through which and a first liquid is acquired positional information about the substrate;
a second optical member that emits the exposure beam;
a first movable member that holds the substrate and is capable of moving within a prescribed area that includes a first position, which opposes the first optical member, and a second position, which opposes the second optical member; and
a first liquid holding member that can be positioned at the first position;
wherein,
by disposing at least one of the first movable member and the first liquid holding member at the first position, a first space, which is capable of holding the first liquid, continues to be formed between at least one of the first movable member, the substrate, which is held by the first movable member, and the first liquid holding member on one side and the first optical member on the other side.

2. An exposure apparatus according to claim 1, wherein the first liquid holding member is disposed at the first position at least during the exposure of the substrate, which is held by the first movable member.

3. An exposure apparatus according to claim 1, further comprising:
a supply port that supplies the first liquid.

4. An exposure apparatus according to claim 1, further comprising:
a first holding apparatus that holds the first liquid holding member at the first position.

5. An exposure apparatus according to claim 4, wherein the first holding apparatus chucks the first liquid holding member.

6. An exposure apparatus according to claim 5, wherein
the first holding apparatus comprises:
a holding surface that holds the first liquid holding member; and
a suction port that chucks the first liquid holding member.

7. An exposure apparatus according to claim 6, wherein the suction port is capable of recovering the first liquid.

8. An exposure apparatus according to claim 1, further comprising:
a second holding apparatus that releasably holds the first liquid holding member to the first movable member.

9. An exposure apparatus according to claim 8, wherein the second holding apparatus holds the first liquid holding member at least while acquiring positional information about the substrate through the first optical member.

10. An exposure apparatus according to claim 1, wherein the acquisition of positional information about the substrate comprises detecting an alignment mark on the substrate.

11. An exposure apparatus according to claim 1, further comprising:
a second movable member that holds the substrate and is capable of moving within a prescribed area that includes the first position and the second position;
wherein,
by disposing at least one of the first movable member, the second movable member, and the first liquid holding member at the first position, the first space continues to be formed between at least one of the first movable member, the substrate held by the first movable member, the second movable member, the substrate held by the second movable member, and the first liquid holding member on one side and the first optical member on the other side.

12. An exposure apparatus according to claim 1, wherein the exposure beam that is emitted from the second optical member is irradiated on the substrate through a second liquid.

13. An exposure apparatus according to claim 12, further comprising:
a second movable member that holds the substrate and is capable of moving within a prescribed area that includes the first position and the second position;
wherein,
by disposing at least one of the first movable member and the second movable member at the second position, the second space, which is capable of holding the second liquid, continues to be formed between at least one of the first movable member, the substrate held by the first movable member, the second movable member, and the substrate held by the second movable member on one side and the second optical member on the other side.

14. An exposure apparatus according to claim 12, further comprising:
a second liquid holding member that can be positioned at the second position;
wherein,
by disposing at least one of the first movable member and the second liquid holding member at the second position, the second space, which is capable of holding the second liquid, continues to be formed between at least one of the first movable member, the substrate held by the first movable member, and the second liquid holding member on one side and the second optical member on the other side.

15. An exposure apparatus according to claim 14, wherein the second liquid holding member comprises a measuring instrument that is capable of acquiring information related to exposure.

16. An exposure apparatus according to claim 15, wherein the second liquid holding member does not hold the substrate.

17. An exposure apparatus according to claim 14, further comprising:
a third holding apparatus that holds the second liquid holding member at the second position.

18. An exposure apparatus according to claim 17, further comprising:
a fourth holding apparatus that detachably holds the second liquid holding member to the first movable member.

19. An exposure apparatus according to claim 18, wherein the fourth holding apparatus holds the second liquid holding member at least while an immersion exposure of the substrate is performed through the second optical member and the second liquid.

20. A device fabricating method comprising;
exposing a substrate by use of the exposure apparatus according to claim 1; and
developing the exposed substrate.

21. An exposing method for exposing a substrate with an exposure beam, the method comprising:
holding the substrate to a movable member;
acquiring positional information about the substrate, which is held by the movable member, through a first liquid and a first optical member;
after the positional information about the substrate is acquired, irradiating the substrate, which is held by the movable member, with the exposure beam through a second optical member and a second liquid; and
after the positional information about the substrate is acquired and before an exposure of the substrate, which is held by the movable member, starts, disposing a liquid holding member at a position that opposes the first optical member so as to continue forming a space, which is capable of holding the first liquid, between the liquid holding member and the first optical member.

22. An exposing method according to claim 21, wherein the first liquid continues to be held between the liquid holding member and the first optical member during the exposure of the substrate, which is held by the movable member.

23. An exposing method according to claim 21, wherein the liquid holding member is held by the movable member during the acquisition of the positional information about the substrate.

24. An exposing method according to claim 23, wherein, before the acquisition of the positional information about the substrate, the movable member holds the liquid holding member held by the movable member, which has been released from a position opposing the first optical member.

25. An exposing method according to claim 23, wherein, after the acquisition of the positional information about the substrate and before the exposure of the substrate, the liquid holding member is released from the movable member.

26. An exposing method according to claim 21, further comprising:
executing an operation of exchanging the substrate after the exposure of the substrate held by the movable member,
wherein
the first liquid continues to be held between the liquid holding member and the first optical member during the operation of exchanging the substrate.

27. An exposing method for exposing a substrate with an exposure beam, the method comprising:
holding a substrate to a first movable member;
acquiring positional information about the substrate, which is held by the first movable member, in a state in which a first liquid is held between the substrate held by the first movable member and a first optical member;
exposing the substrate held by the first movable member through a second optical member and a second liquid after the acquisition of the positional information about the substrate held by the first movable member;
holding a substrate to a second movable member;
acquiring positional information about the substrate, which is held by the second movable member, in a state in which the first liquid is held between the substrate held by the second movable member and the first optical member; and
exposing the substrate held by the second movable member through the second optical member and the second liquid after the exposure of the substrate held by the first movable member and before the acquisition of the positional information about the substrate held by the second movable member,
wherein
the first liquid continues to be held below the first optical member during transition from a first state in which the first liquid is held between the substrate held by the first movable member and the first optical member to a second state in which the first liquid is held between the substrate held by the second movable member and the first optical member.

28. An exposing method according to claim 27, wherein, after the acquisition of the positional information about the substrate held by the first movable member, a liquid holding member is disposed at a position opposing the first optical member.

29. An exposing method according to claim 28, wherein the first liquid is held between the first optical member and the liquid holding member so that the first liquid continues to be held below the first optical member during the transition from the first state to the second state.

30. An exposing method according to claim 29, further comprising:
holding the liquid holding member, which has been released from the position opposing the first optical member, to the second movable member before the acquisition of the positional information of the substrate held by the second movable member.

31. An exposing method according to claim 28, wherein, when the positional information of the substrate held by the first movable member is acquired, the liquid holding member is held by the first movable member.

32. An exposing method according to claim 31, further comprising:
releasing the liquid holding member from the first movable member after the acquisition of the positional information of the substrate held by the first movable member.

33. A device fabricating method, comprising:
exposing a substrate by use of the exposing method according to claim 21; and
developing the exposed substrate.
